(19) United States
(12) Patent Application Publication
(10) Pub. No.: US 2017/0363953 A1
(43) Pub. Date: Dec. 21, 2017

(54) DEVICE FOR CARRYING OUT A CAPILLARY NANOPRINTING METHOD, A METHOD FOR CARRYING OUT CAPILLARY NANOPRINTING USING THE DEVICE, PRODUCTS OBTAINED ACCORDING TO THE METHOD AND USE OF THE DEVICE

(71) Applicant: Universität Osnabrück, Osnabrück (DE)

(72) Inventors: Martin STEINHART, Osnabrück (DE); Longjian XUE, Osnabrück (DE)

(21) Appl. No.: 15/523,692

(22) PCT Filed: Nov. 3, 2015
(86) PCT No.: PCT/DE2015/100462

§ 371 Date: May 2, 2017

(30) Foreign Application Priority Data
Nov. 3, 2014 (DE) 10 2014 115 969.1

(51) Int. Cl. G03F 7/00; B82Y 40/00; B82Y 10/00; C23F 1/08; G03F 7/095

(52) U.S. Cl. CPC G03F 7/0002; B82Y 40/00; B82Y 10/00; G03F 7/0957; C23F 1/08

(57) ABSTRACT

The present invention relates to a device for carrying out a capillary nanoprinting method, comprising at least one monolithic combination of a substrate (1) and one or more contact elements (2), at least parts of said contact elements (2) having a porous structure, preferably also at least parts of the substrate having a porous structure, particularly the entire monolithic combination having a porous structure.

### TECHNICAL FIELD

The subject matter of the present invention is a technical device for carrying out capillary nanoprinting, the method of capillary nanoprinting which can be carried out with this technical device, fields of ink drops or derived products of fields of these ink drops, which are available by means of capillary nanoprinting, as well as uses of these fields of ink drops and their derived products.

### BACKGROUND

Ballistic application of ink on surfaces to be printed by methods such as inkjet printing_{i, ii} and electrosprayingⁱⁱⁱ relies on the transport of ink droplets accelerated towards the surface to be printed through an amount of space between a nozzle or similar device and the surface to be printed. Ballistic printing however is associated with substantial disadvantages: in the case of inkjet printing drops with volumes considerably above one picolitre are transferred to the surface to be printed; a droplet size in the region above one picolitre represents the lower volume limit, which is technically feasible with inkjet printing. In the case of electrospraying it is not possible to adjust narrow particle size distributions of the ink drops or to precisely position individual ink drops on the surface to be printed. A general inherent disadvantage of ballistic printing methods is that the kinetic energy of the ink drops must be dissipated abruptly when the ink drops hit the surface to be printed. This process of dissipation is associated with physical distortion or atomisation of the ink drops which is difficult to control.

Conventional nano-lithography according to the prior art comprises on the one hand raster probe nano-lithography^{iv-viii} and on the other hand contact-lithographic methods^{ix-xii} which are based on the use of topographic or chemically-structured stamps. Certain embodiments of raster probe nano-lithography permit the supply of an ink to a cantilever tip or to the points of micropipettes^{xiii, xiv} so that liquids can be transferred to other areas via capillary bridges.^{xv-xvii} Raster probe nano-lithography however is a serial method, which only permits successive deposition of ink drops or ink structures with a single cantilever tip. The enscribing of surfaces by means of raster probe nano-lithography between each individual writing/printing step or the deposition of structures, which are greater than the dimensions of the raster probe, require controlled lateral movement either of the raster probe or the surface being printed/enscribed. Since raster probe nano-lithography is an intrinsic serial method with low throughput, only small surfaces can be processed. Depositing fields of ink drops on an area of 100 μm×100 μm thus needs at least several minutes.

Although stamp-based contact-lithographic methods permit printing of large surfaces and can also be implemented as continuous rolling processes.^{xviii} In this case solid, i.e. non-porous stamps are used. It is however disadvantageous that with stamp-based contact-lithographic methods the ink to be deposited must be transferred to the surface to be printed, by the ink being initially adsorbed on the surface of the stamp, the stamp then being applied onto the surface to be printed and then the ink adsorbed on the surface of the stamp being transferred to the surface to be printed. So that a further printing cycle can be implemented in the same quality, first ink must be again adsorbed on the surface of the stamp. The transfer of ink onto the surface of the stamp by adsorption of the ink on the stamp surface is a technically complex additional process step in stamp-based contact-lithographic methods, which can require up to several minutes for each cycle.^{xii} The adsorption of ink by the stamps in some cases requires complex mechanical devices for moving the stamps to the ink reservoirs and for providing the ink by means of a system which enables controlled adsorption of ink by the stamps over a boundary surface between stamp and ink reservoir. A further disadvantage of stamp-based contact-lithographic methods according to the prior art consists in that these only permit the transmission of thin layers made up of one or few molecular monolayers of the material to be printed.

### SUMMARY

It is therefore the objective of the present invention to provide a device and a printing method for generating fields of ink drops which permits the disadvantages of the prior art, in particular a decrease in the volumes of the drops produced to be overcome as well as their precise positioning on a surface. Furthermore it is an objective of the present invention to provide a device and a printing method which permit the simultaneous generation of a large number of discrete ink drops on a surface to be printed, large-scale generation of fields of discrete ink drops on a surface to be printed as well as control of the physical distortion of the ink drops. In addition it is an objective of the present invention to provide a corresponding device by means of which initial application of the ink, intended for producing the drops, onto the surface of a stamp can be avoided.

This objective is achieved according to the invention by a device for carrying out a capillary nanoprinting method, comprising at least one monolithic combination of a substrate and one or more contact elements, at least parts of the contact elements having a porous structure, preferably also at least parts of the substrate having a porous structure, particularly preferably the entire monolithic combination having a porous structure. Said porous structure has the function of supplying the ends of the contact elements facing away from the substrate with ink as a result of the monolithic combination of a substrate and contact elements.

Preferably it is proposed that the porous structure present at least in parts of the monolithic combination of a substrate and one or more contact elements is implemented so that ink can be supplied to the ends of the contact elements facing away from the substrate through the porous structure. For example it is conceivable that the porous structure contains parallel-arranged cylindrical pores. It is particularly preferred that the porous structure present at least in parts of the monolithic combination of a substrate and one or more contact elements contains a continuous pore system. It is particularly preferred that parts, having porous structures, of the monolithic combinations of a substrate and one or more contact elements in their entirety have a bi-continuous interpenetrating morphology, a continuous pore system being a component of this bi-continuous interpenetrating morphology.

Preferably a porous structure, having an isotropic or anisotropic continuous pore system, which is preferably a component of a bi-continuous interpenetrating morphology, is proposed.

Preferably it is proposed that the surface of the monolithic combination of substrate and contact elements has pore openings at least in parts and preferably the surface of the contact elements has pore openings at least in parts.

In addition it may be proposed that the portion of the pore openings in the total surface of the monolithic combination of substrate and contact elements is greater than 10%, preferably greater than 25%, in particular preferably greater than 40%.

Particularly preferably it is proposed that the monolithic combination of substrate and contact elements contains at least one material, which is selected from the group, consisting of:
i) organic polymers such as poly(p-xylene), polyacrylamide, polyimides, polyesters, polyolefins, polystyrenes, polycarbonates, polyamides, polyethers, polyphenyls, polysilanes, polysiloxanes, polybenzimidazoles, polybenzthiazoles, polyoxazoles, polysulfides, polyester amides, polyarylene vinylenes, polylactides, polyetherketones, polyurethanes, polysulfones, inorganic and organic hybrid polymers, polyacrylates, silicones, fully aromatic co-polyesters, poly N vinylpyrrolidone, polyhydroxyethyl methacrylate, polymethyl methacrylate, polyethylene teraphthalate, polybutylene teraphthate, polymethacrylic nitrile, polyacrylic nitrile, polyvinyl acetate, neoprene, Buna N, polybutadiene, polyethylene,
ii) fluorine-containing polymers such as polyvinylidene difluoride, polytrifluorethylene, polytetrafluoroethylene, polyhexaflouropropylene,
iii) dendrimers and/or star-shaped polymers and/or comb-like polymers,
iv) biological polymers such as polysaccharides, cellulose (modified or non-modified), alginates, polypeptides, collages, DNA, RNA,
v) polymers, which are composed of at least two different repeating units, preferably in the form of statistical copolymers and/or block copolymers and/or graft copolymers and/or dendrimers,
vi) block copolymers, which contain at least two blocks of different polarity, said blocks being selected inter alia from polystyrene blocks and/or polyisoprene blocks and/or polybutadiene blocks and/or polypropylene blocks and/or polyethylene blocks and/or poly (methylmethacrylate)-blocks and/or poly (vinylpyridin)-blocks and/or poly (vinylpyrrolidone)-blocks and/or poly (vinyl alcohol)-blocks and/or poly (ethyl oxide)-blocks and/or poly (propylene oxide)-blocks and/or poly (butylmethacrylate)-blocks and/or poly (N-isopropyl acrylamide)-blocks and/or poly (dimethylsiloxane)-blocks and/or polyacrylate blocks and/or poly (vinyl acetate)-blocks and/or poly (vinylidene difluoride)-blocks and/or polythiophene blocks and/or poly (styrene sulfonate)-blocks,
vii) copolymers, which preferably contain fluorine-containing comonomers, fluorine-containing comonomers which are derived from fluoroethylene, difluoroethylene, trifluoroethylene, tetrafluoroethylene or hexafluoropropylene.
viii) conductive and/or semiconducting polymers,
ix) polyelectrolytes,
x) combinations of two or more polymers and/or inorganic materials,
xi) metals, preferably gold, silver, platinum, palladium, tungsten, copper, titanium, aluminium, tantalum,
xii) any mixtures of different metals,
xii) oxides, which contain at least one metal and oxygen or at least one semiconductor and oxygen, preferably silicon oxide, titanium oxide, aluminium oxide and tantalum oxide,
xiii) inorganic semiconductors, preferably silicon,
and mixtures thereof.

Furthermore it may be proposed that the contact elements are cylindrical, rod-shaped, spherical, hemispherical, rectangular, square or strip-shaped.

Preferably it may be proposed that the ends of the contact elements facing away from the substrate are hemispherical, pyramidal or even.

It is preferred that the contact elements are tubular.

It is particularly preferred that the side of the substrate facing away from the contact elements is connected to a further porous layer.

It may preferably be proposed that the substrate is cylindrical or cylinder jacket-shaped and the contact elements are arranged on the outer surface of the cylindrical or cylinder jacket-shaped substrate.

Furthermore the objective can be achieved by a method for carrying out a capillary nanoprinting, comprising the steps:
a) providing an inventive device;
b) providing a surface to be printed;
c) providing an ink in at least one part of the porous structure of the monolithic combination;
d) reducing the distance between the surface to be printed and the contact elements, in order to form one or more capillary bridges consisting of ink between the contact elements and the surface to be printed; and
e) subsequently increasing the distance between the contact elements and the surface to be printed, it being possible to keep the contact elements and the surface apart from one another at a specific constant distance for a selected time after being brought near each other and before the distance is increased or however it being possible to increase the distance immediately after contact elements and surface have been brought near each other.

Likewise the objective is achieved by a method for carrying out capillary nanoprinting, comprising the steps:
a) providing an inventive device;
b) providing a surface to be printed;
c) providing an ink in at least one part of the porous structure of the monolithic combination;
d) reducing the distance between the surface to be printed and the contact elements, whereby reducing the distance between the surface and the contact elements can take place before or after providing an ink in at least one part of the porous structure of the monolithic combination;
e) moving the surface to be printed so as to contact the inventive device, in which the monolithic combination of substrate and contact elements implements a rotational movement about its longitudinal axis, or rolling the monolithic combination of substrate and contact elements contained in an inventive device over the surface.

In this case it is preferred according to the invention that the ink is advanced to the contact elements continuously or in phases.

It is preferred that reducing and/or increasing the distance between the contact elements and the surface to be printed is carried out at a speed of maximum 1 μm per second, preferably 100 nm per second, particularly preferably 10 nm per second.

It is particularly preferred that formation of the capillary bridge consisting of ink is detected by measuring the force necessary for bringing the substrate and contact elements near to each other and/or by creating an electrical contact between the monolithic combination of substrate and contact elements as well as the surface to be printed.

It is likewise preferred that the method is carried out in the presence of an electric and/or magnetic field.

It is further preferred that the surface to be printed is covered with a liquid, which is not identical to the ink and is called matrix liquid in the following, and that ink drops, which, unless their surface is in contact with the printed surface, is encapsultated by said matrix liquid, are produced on the surface to be printed by capillary nanoprinting. It may be proposed that the matrix liquid, the ink drops or both the matrix liquid and the ink drops are completely or partially solidified.

The objective is also achieved by a field of ink drops or their derived products on a surface, preferably obtained according to the inventive method.

It is particularly preferably proposed that the ink drops forming the field or their derived products in each case have a volume of maximum one picolitre, preferably one ferntolitre, particularly preferably one attolitre.

Furthermore the objective is achieved by a field of wires or their derived products on a surface obtained according to the inventive method. The wires or their derived products can be present in this case oriented perpendicularly to the surface. Likewise the longitudinal axes of the wires or their derived products can be inclined relative to the surface, so that the angle included by the surface and the longitudinal axes is less than 90°, preferably less than 75° and particularly preferably less than 60°.

Furthermore it may be proposed that the wires or their derived products have a diameter of less than 500 nm, preferably 100 nm, particularly preferably 30 nm.

In addition preferably it may be proposed that the wires or their derived products have a length of more than 500 nm, preferably more than 1 μm, particularly preferably more than 5 μm.

Furthermore it may be proposed that the ink drops or wires or their derived products at least partly consist of liquid. Likewise however it can be proposed that the ink drops or wires are completely or partially solidified.

The objective is equally achieved by a field of coatings or of their derived products on a surface, preferably obtained according to the inventive method.

In this case it is preferred that the coatings or their derived products in each case have a diameter of less than one micrometre, preferably less than 100 nm, and particularly preferably less than 20 nm.

The field of ink drops and/or wires and/or coatings and/or derived products of ink drops and/or wires and/or coatings can preferably have a surface of at least 100 square micrometres, particularly preferably at least one square millimetre, and most preferably at least one square centimetre.

Preferably the ink drops forming the field and/or wires and/or coatings and/or derived products of ink drops and/or wires and/or coatings in each case have a distance to their nearest neighbours within the field of less than one micrometre, preferably less than 500 nm and particularly preferably less than 100 nm.

Furthermore it is preferred that the field of ink drops and/or wires and/or coatings and/or derived products of ink drops and/or wires and/or coatings has a surface density of more than one ink drop or one wire or one coating or one derived product per square micrometre, preferably more than 10 ink drops and/or wires and/or coatings and/or derived products per square micrometre, particularly preferably more than 130 ink drops and/or wires and/or coatings and/or derived products per square micrometre.

Still more preferably the ink drops forming the field and/or wires and/or coatings and/or derived products of ink drops and/or wires and/or coatings form a regular lattice, preferably a square lattice, particularly preferably a hexagonal lattice.

The objective is finally achieved by using the inventive device for producing fields of totally or partially solidified ink drops and/or fields of totally or partially liquid ink drops and/or fields of totally or partially solidified nanowires and/or fields of totally or partially liquid nanowires and/or fields of nanoparticles and/or fields of dot-like coatings on the surface to be printed and/or fields of the pores present in the surface to be printed. The inventive device, the inventive method, the inventive fields of ink drops as well as the inventive applications are described below in detail with reference to the figures.

### DRAWINGS

FIG. 1: Exemplary illustration of capillary nanoprinting. a) A monolithic combination of a substrate (1) and contact elements (2), which has a continuous pore system, is filled with ink. b) If the monolithic combination of substrate (1) and contact elements (2) is brought near the surface to be printed (3), capillary bridges (4) consisting of ink form between contact elements (2) and surface (3) to be printed. c) If the monolithic combination of substrate (1) and contact elements (2) is again drawn back from the surface to be printed (3), the capillary bridges consisting of ink (4) tear apart in a controlled way, and fields of ink drops (5) remain behind on the surface to be printed (3).

FIG. 2: Examples of contact geometries of the contact elements (2), which with a substrate (1) form a monolithic combination. a) Hemispherical contact elements (2); b) tubular contact elements (2) with a continuous cylindrical cavity, through which ink (4) can flow to the surface to be printed.

FIG. 3: Exemplary embodiment of capillary nanoprinting in a continuous rolling mode. The monolithic combination of substrate (1) and contact elements (2) is a component of a roller; ink (4) is fed to the monolithic combination of substrate (1) and contact elements (2) via a roller core and the side of the substrate (1) facing away from the contact elements (2). As the result of a rotational movement of the roller with the monolithic combination of substrate (1) and contact elements (2), a surface (3), which is guided past the roller at a speed adapted to the rotary speed of the roller, can be printed with ink drops (5).

FIG. 4: Exemplary illustration of capillary nanoprinting on a surface to be printed, which is covered with a matrix liquid. a) A monolithic combination of substrate (1) and contact elements (2), filled with ink, is brought near to a surface to be printed (3), which is covered with a matrix liquid (6). b) In the course of being brought near to the surface, the contact elements (2) dip into the matrix liquid (6) and capillary bridges consisting of ink (4) form within the matrix liquid (6) between the contact elements (2) and the surface to be printed (3). c) After contact elements (2) and printed surface (3) have separated, the capillary bridges consisting of ink (4) tear, so that fields of ink drops (5) which, except on the contact area between ink drops (5) and printed surface (3) are completely encapsulated by matrix liquid (6), are deposited on the printed surface (3).

FIG. 5: Generation of fields of wires (7) by capillary nanoprinting. a) Bringing contact elements (2) filled with ink near to the surface to be printed (3) leads to the formation of capillary bridges consisting of ink (4) between the contact elements (2) and the printed surface (3). b) Contact elements (2) and printed surface (3) separate in such a manner that the capillary bridges consisting of ink (4) do not break. Instead these are solidified starting from the printed surface (3), so that the solidification front separates a solidified segment (8) of the capillary bridge consisting of ink on the side of the printed surface (3) from a liquid part (9) of the capillary bridge in contact with the contact elements (2). c) As a result of suitable measures such as interruption of the ink supply to the contact elements (2) or increase in the separation speed of contact elements (2) and printed surface (3) the capillary bridges tear, so that fields of wires are generated on the printed surface (3).

FIG. 6. Exemplary illustration of the use of nano-drop fields for nano-drop lithography. a) Nano-drop arrays (5) are deposited on a surface (3) by capillary nanoprinting. b) In an alternative embodiment the nano-drop arrays (5) serve as mask for modifying the surface (3) with a further layer (10). Removal of the further layer (10) produces layer (10) as free standing membrane with pores at the positions of the nano-drops (5). d) If the nano-drops (5) consist of corrosive ink, in a further alternative embodiment recesses (11) can be etched in material (12) at the positions, where nano-drops were deposited. e) The recesses (11) serve as nuclei in order to etch pores (13) at the positions of the recesses (11) in surface (3) by means of suitable etching processes.

FIG. 7: Metal-assisted etching of silicon by capillary nanoprinting. a) Fields of drops of an ink (5), which contain precursor compounds for suitable metals, are applied on silicon wafers (14) and the precursor compounds of the metals are converted into the metals concerned. As a result fields of metal nanoparticles (15) arise. b) Pores develop at the positions of the metal nano-particles (15) by way of metal-assisted etching. c) In a further alternative embodiment first fields of drops of an ink are applied on a silicon wafer (14) by capillary nanoprinting (5). Subsequently the silicon wafer is coated by appropriate methods with a metal (16), suitable for metal-assisted etching. By way of metal-assisted etching silicon nano-rods remain behind at the positions of the ink drops (5), since metal (16) is not in contact with Si there.

FIG. 8: a) Pseudo Ergodic laboratory in nano-drop configuration. Dense fields of ink drops (5) are deposited on a transparent surface (3) covered with matrix liquid (6) by means of capillary nanoprinting. The ink drops (5) are encapsulated resulting from solidification of the matrix liquid (6), the solidified matrix liquid (6) preferably being transparent. Preferably the fields of encapsulated ink drops (5) are implemented so that the individual ink drops are microscopically soluble. The focus volume (17) of a confocal laser scanning microscope is illustrated by way of example. b) Lab on chip configuration. Fields of dot-like ink drops, which after solidification form dot-like coatings (18), on which in turn analyte molecules can be immobilised, are generated by means of capillary nanoprinting. The fields of the dot-like coatings (18) are preferably implemented in such a way that individual dot-like coatings are microscopically soluble. In turn the focus volume (17) of a confocal laser scanning microscope is illustrated by way of example. In both examples illustrated in FIG. 8 it is also conceivable to dissolve the ink drops or their derived products by total internal reflection fluorescence microscopy for example.

### DETAILED DESCRIPTION

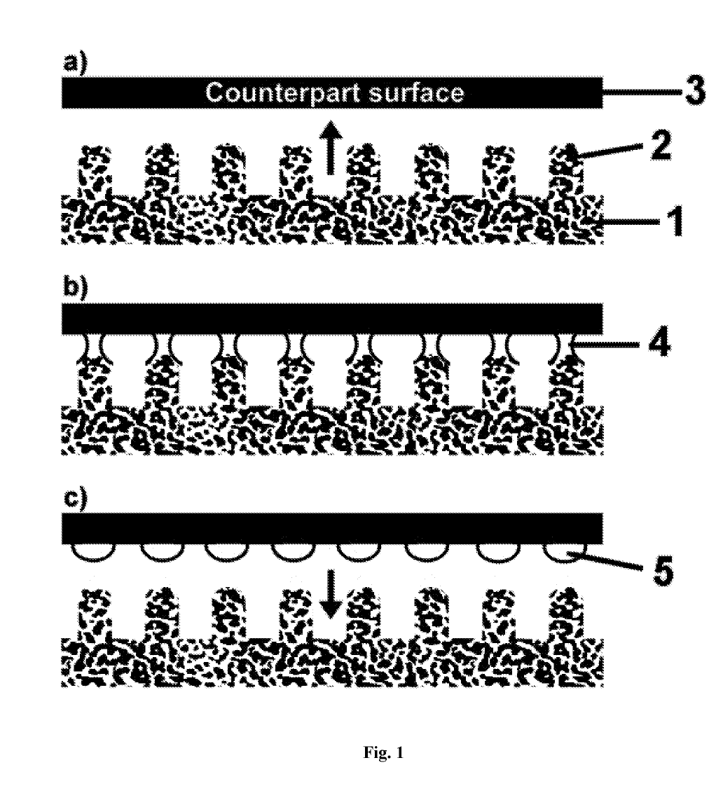

The fields of ink drops, produced by means of capillary nanoprinting, in this case preferably have areas greater than 100 square micrometres, particularly preferably areas greater than one square millimetre and most preferably greater than one square centimetre. Said ink drops forming fields preferably have volumes of under one picolitre, particularly under one ferntolitre, and most preferably under one attolitre. The basic principle of capillary nanoprinting is illustrated by way of example in FIG. 1: a substrate (1) as well as contact elements (2) connected to substrate (1) completely or partially contain a porous structure, which preferably has average pore sizes of less than 500 nm, particularly preferably average pore sizes of less than 100 nm and most preferably average pore sizes of less than 50 nm. The contact elements (2) however have said porous structure in each case. The substrate (1) with the contact elements (2) forms a monolithic combination. The porous structure contained in the monolithic combination of substrate (1) and contact elements (2) is continuous in its entire expanse within the monolithic combination of substrate (1) and contact elements (2). Therefore the monolithic combination of substrate (1) and contact elements (2) has the property that the fluid phases can be transported through their total amounts of space or through those of their parts, which have the continuous pore system. The volume of the pore system of the monolithic combination of substrate (1) and contact elements (2) can therefore be filled totally or partially with any liquid acting as ink. If the contact elements are brought into near contact with a surface to be printed (3), capillary bridges (4) consisting of ink form between the contact elements filled with ink (2) and the surface to be printed (3). If the monolithic combination of substrate (1) and contact elements (2) is again removed from the surface to be printed (3), tearing apart of the capillary bridges consisting of ink (4) occurs in a controlled way. Fields of ink drops (5) remain on the surface to be printed (3), the positions of the ink drops (5) are defined by the arrangement of the contact elements (2). The surface to be printed (3) can be present in the form of a strip of the material, as two-dimensional planar structure of any form such as film, foil or profile. Likewise the surface to be printed (3) can be present as a three-dimensional body and curved in one or more spatial directions.

The technical device for carrying out capillary nanoprinting therefore contains at least one monolithic combination of substrate (1) and contact elements (2), which in turn completely or partially contains a continuous pore system. In this case it is advantageous if the surface of the monolithic combination of substrate (1) and contact elements (2) has pore openings. The portion of the pore openings in the total surface of the monolithic combination of substrate (1) and contact elements (2) is preferably greater than 10%, particularly preferably greater than 25%, most preferably greater than 40%. In an advantageous exemplary alternative embodiment the monolithic combinations of substrate (1) and contact elements (2) have hexagonal fields of contact elements (2) with diameters of ˜60 nm, nearest-neighbour distances of ˜100 nm as well as surface densities of ˜130 contact elements (2) per μm² over a total area of 9 cm².

The monolithic combination of substrate (1) and contact elements (2) preferably contains at least one material or several materials selected from:

i) organic polymers such as poly(p-xylene), polyacrylamide, polyimides, polyesters, polyolefins, polystyrenes, polycarbonates, polyamides, polyethers, polyphenyls, polysilanes, polysiloxanes, polybenzimidazoles, polybenzthiazoles, polyoxazoles, polysulfides, polyester amides, polyarylene vinylenes, polylactides, polyetherketones, polyurethanes, polysulfones, inorganic and organic hybrid polymers, polyacrylates, silicones, fully aromatic co-polyesters, poly N vinylpyrrolidone, polyhydroxyethyl methacrylate, polymethyl methacrylate, polyethylene teraphthalate, polybutylene teraphthate, polymethacrylic nitrile, polyacrylic nitrile, polyvinyl acetate, neoprene, Buna N, polybutadiene, polyethylene,
ii) fluorine-containing polymers such as polyvinylidene difluoride, polytrifluorethylene, polytetrafluoroethylene, polyhexaflouropropylene,
iii) dendrimers and/or star-shaped polymers and/or comb-like polymers,
iv) biological polymers such as polysaccharides, cellulose (modified or non-modified), alginates, polypeptides, collages, DNA, RNA,
v) polymers, which are composed of at least two different repeating units, preferably in the form of statistical copolymers and/or block copolymers and/or graft copolymers and/or dendrimers,
vi) block copolymers, which contain at least two blocks of different polarity, whereby said blocks can be selected inter alia from polystyrene blocks and/or polyisoprene blocks and/or polybutadiene blocks and/or polypropylene blocks and/or polyethylene blocks and/or poly (methylmethacrylate)-blocks and/or poly (vinylpyridin)-blocks and/or poly (vinylpyrrolidone)-blocks and/or poly (vinyl alcohol)-blocks and/or poly (ethyl oxide)-blocks and/or poly (propylene oxide)-blocks and/or poly (butylmethacrylate)-blocks and/or poly (N-isopropyl acrylamide)-blocks and/or poly (dimethylsiloxane)-blocks and/or polyacrylate blocks and/or poly (vinyl acetate)-blocks and/or poly (vinylidene difluoride)-blocks and/or polythiophene blocks and/or poly (styrene sulfonate)-blocks,
vii) copolymers, which contain fluorine-containing comonomers, preferably fluorine-containing comonomers which are derived from fluoroethylene, difluoroethylene, tri fluoroethylene, tetrafluoroethylene or hexafluoropropylene,
viii) conductive and/or semiconducting polymers,
ix) polyelectrolytes,
x) combinations of two or more polymers and/or inorganic materials,
xi) metals such as gold, silver, platinum, palladium, tungsten, copper, titanium, aluminium, tantalum,
xii) any mixtures of different metals,
xii) oxides, which contain at least one metal and oxygen or at least one semiconductor and oxygen, as for instance silicon oxide, titanium oxide, aluminium oxide and tantalum oxide,
xiii) inorganic semiconductors such as silicon.

The contact elements (2) may be produced with any method for topographic surface structuring. An example of this is topographic surface structuring by focused ion beams. A further example is lithographic structuring of layers consisting of a positive or negative resist, for instance by means of electron beam lithography or by means of optical lithography or by means of interference lithography. The actual topographic structuring follows this lithographic structuring step for fabricating the contact elements (2), which for example can involve wet-chemical etching or reactive ion etching.

A preferred method for fabricating contact elements (2) is to mould stencils or templates. These stencils or templates have a topographic structure, which represents the negative of the desired topographic structure of the contact elements (2) and may be fabricated in turn by suitable combinations of lithographic and topographic structuring. Moulding the templates therefore produces contact elements (2) with the desired topography, which in turn is a structurally inverse copy of the template topography. As an example the use of templates fabricated from elastomer, cross-linked polydimethylsiloxane for example or cross-linked polyurethane, metal, silicon or inorganic oxides is advantageous. Likewise however self-organsisation processes can be used for moulding the templates. An example of a template, which is fabricated by means of self-organisation, is self-organised nano-porous aluminium oxide.^{xix, xx} Porous aluminium oxide polymer-wire fields having areas of several cm³ can be produced by moulding.^{xxi} A further example of fabricating contact elements (2) by moulding templates obtained through self-organisation is producing monolayers consisting of nano- or microspheres, whereby for high throughput production of monolithic combinations of substrate (1) and contact elements (2) a multi-stage moulding method, which is already prior art can be adapted.^{xxii-xxiv} In this case master templates moulded from elastomer, for example cross-linked polydimethylsiloxane or cross-linked polyurethane, metal, silicon or inorganic oxides can be produced by moulding monolayers consisting of nano- and microspheres, which in turn can be used for fabricating the contact elements (2) in further moulding steps.

Any templates for fabricating the contact elements (2) can be moulded in various ways. If the monolithic combinations of substrate (1) and contact elements (2) consist of polymer, the templates can be moulded for example by hot-pressing, by infiltration of polymer solutions into the template or by gaseous phase deposition of precursor compounds of the polymer. If the monolithic combinations of substrate (1) and contact elements (2) consist of metal, electro-chemical deposition, electroless deposition, atomic layer deposition or other forms of gaseous phase deposition inter alia can be used, in order to mould the template with the desired metal or with suitable precursor compounds for the desired metal (which are then converted into the desired metal). Likewise infiltration into the templates of mixtures consisting of a precursor compound of the desired metal as well as of polymers and/or structure-directing compounds such as surfactants or block copolymers as solution or melt, the precursor compounds of the desired metals being converted into the desired metals and all other components of the mixture being removed for example by extraction or chemical decomposition or thermal decomposition. If the monolithic combinations of substrate (1) and contact elements (2) consist of oxide, the template can be moulded inter alia, by the contact elements being produced by means of sol-gel chemistry in the template or by means of thermolysis of suitable precursor compounds in the template. In each case the substrate (1) originates from the material used for moulding, which is present on the surface of the template.

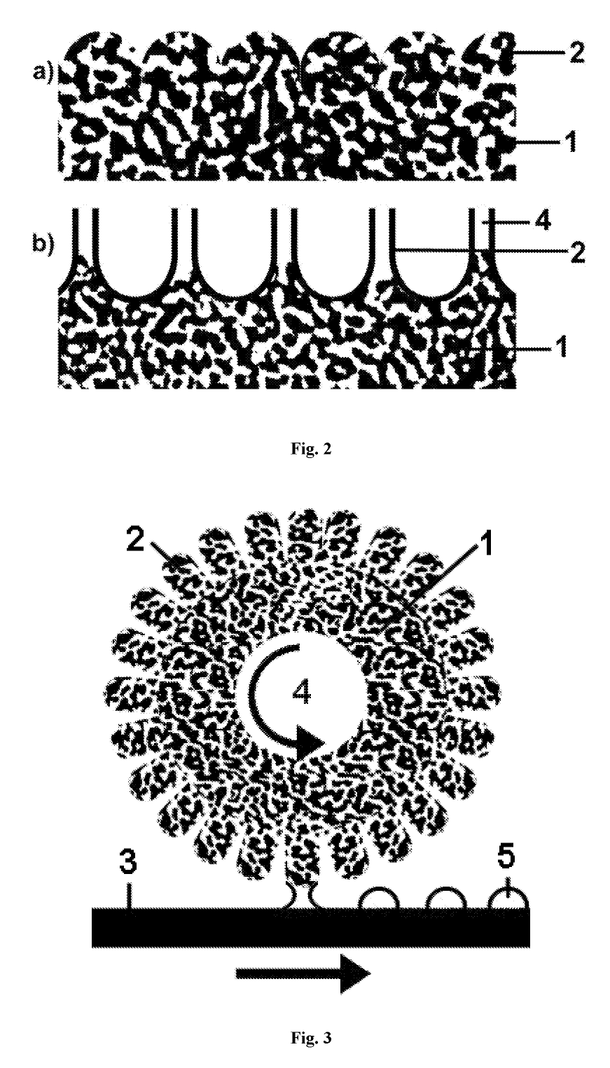

The contact elements (2) can be cylindrical in form, the cylinder axis being perpendicular to the plane of the substrate (1) or also can be inclined towards the surface of the substrate. In further advantageous alternative embodiments of the monolithic combinations of substrate (1) and contact elements (2) the contact elements (2) are spherical to hemispherical, rectangular, square, pyramidal or strip-shaped. It is however also conceivable that the contact elements form any pattern, which is available by lithographic and/or topographic structuring. The ends of the contact elements (2) facing away from the substrate (1), which are brought into proximity with the surface to be printed (3), can also possess different contact geometries. For example the contact elements can be hemispherical (FIG. 2a), pyramidal with a tip pointing towards the surface to be printed (3) or even. Likewise the contact elements can be tubular (FIG. 2b), so that these have a continuous cylindrical cavity, through which ink can be transported from substrate (1) to a surface to be printed (3).

It is proposed to implement the pore system in the monolithic combinations of substrate (1) and contact elements (2) in such a way that ink (4) can be supplied through this to the ends of the contact elements (2) facing away from the substrate (1). For example cylindrical pores parallel-arranged in the pore system may be produced to this end. It is particularly advantageous however if the pore system is continuous in all spatial directions. For example the parts containing the porous structure of monolithic combinations of substrate (1) and contact elements (2) or however in entirely porous monolithic combinations of substrate (1) and contact elements (2) can have a bi-continuous interpenetrating morphology, in which the continuous pore system is a component. It is equally conceivable to derive the pore system from a block copolymer which has a so-called gyroide structure. For generating the continuous pore system in the monolithic combinations of substrate (1) and contact elements (2) the following methods inter alia can be used:

(i) If mixtures of at least two polymer materials or of at least one polymer material and at least one further non-polymeric component are used as raw material, a spinodal decomposition can be induced by a change of temperature, at least one component being removed for example by extraction or by chemical decomposition or by thermal decomposition from the spinodally decomposed mixture obtained in this way.
ii) In mixtures of at least one polymer and at least one vaporisable component, spinodal decomposition can be induced by a change of temperature and/or by evaporation of the vaporisable component/s, the pore structure being obtained by solidification of at least one polymeric component by crystallisation and/or glazing at a selected point in time as well as evaporation of the vaporisable component.
iii) If block copolymers are used as raw material, continuous pore systems can be generated by removing a component by selective chemical decomposition^{xxv} or by swelling-induced morphology reconstruction, as described in xxvi-xxix.
iv) If mixtures of at least one block copolymer and at least one further removable component are used as raw material, continuous pore systems can be generated by removing at least one further removable component for example by selective chemical decomposition, by selective thermal decomposition or by extraction. An example of this is connected hydrogen bridge bond-assisted self-organisation of block copolymers such as PS-b-P2VP and low-molecular additives such as 3-n-pentadecyphenol^{xxx} in conjunction with removing the low-molecular additive.
v) Spinodal decomposition of a mixture, which contains at least one cross-linkable component, combined with cross-linking at least one cross-linkable component, poly (styrene divinylbenzol) representing an example of a cross-linkable component.
vi) Preparation of an interpenetrating network of non-mixable homopolymers and the corresponding block copolymer combined with cross-linking of one of the networks and removing the other.^{xxxi}
vii) If monolithic combinations of substrate (1) and contact elements (2) consist of metal, a continuous pore structure can first be produced by at least one of the methods i)-vi), in order then to mould these with metal and afterwards to remove all other components for example by means of chemical decomposition, by means of thermal decomposition or by means of extraction. Moulding with metal can take place inter alia by electro-chemical deposition, electroless deposition, atomic layer deposition or other forms of gaseous phase deposition, in order to mould the existing pore structure with the desired metal or with suitable precursor compounds for the desired metal (which are then converted into the desired metal). Equally moulding can take place by infiltration of precursor compounds for the metals or mixtures, which contain such precursor compounds, followed by conversion of said precursor compounds into the metals, of which the monolithic combinations of substrate (1) and contact elements (2) is to consist. viii) If monolithic combinations of substrate (1) and contact elements (2) consist of metal, in mixtures of a precursor compound of the desired metal and structure-directing compounds such as surfactants and/or amphiphilic block copolymers the pore structure can be produced by the structure-directing effect of the structure-directing compounds. In this case the precursor compounds for the desired metal first segregate into compartments of specific polarity defined by the structure-directing compounds. Afterwards the precursor compound for the desired metal is converted into the desired metal and all other components are removed by chemical decomposition and/or thermal decomposition and/or extraction.
ix) If monolithic combinations of substrate (1) and contact elements (2) consist of metal, spinodal decomposition can be generated in a mixture, which consists at least of a precursor compound for a metal and a further component, by a change of temperature or change of the composition of the mixture, all components, which are not metal or metal precursor compounds, being removed by evaporation and/or by extraction and/or by thermal decomposition and/or by chemical decomposition after at least one precursor compound for a metal has been converted into the metal concerned.
x) If monolithic combinations of substrate (1) and contact elements (2) consist of metal, first a metal alloy, which contains two or more metals, can be used. In the remaining component or in the remaining components a pore system is produced by initiating decomposition and subsequent removal of at least one of the components of the alloy.
xi) If monolithic combinations of substrate (1) and contact elements (2) consist of oxides, a continuous pore structure can first be produced by at least one of the methods i)-vi), in order then to mould this with oxide and afterwards to remove all other components for example by means of chemical decomposition, by means of thermal decomposition or by means of extraction. Moulding with oxide can take place inter alia by infiltration of the existing pore system with sol solutions, so that the desired oxides are produced in the existing pores by sol-gel chemistry. Likewise it is possible to infiltrate the existing pore system with solutions containing precursor compounds which can be converted by thermolysis into the desired oxide. Furthermore precursor compounds for the desired oxides can be deposited into the existing pore system by means of gaseous phase deposition, preferably atomic layer deposition, the precursor compounds being converted into the desired oxide by means of a suitable method.
xii) If monolithic combinations of substrate (1) and contact elements (2) consist of oxide, a mixture of at least one precursor compound for oxide and at least one amphiphilic structure-directing compound, for example a surfactant or a blockcoplymer, can be used, in which at least one precursor compound for oxide is converted into oxide by means of sol-gel chemistry and/or thermolysis, while the amphiphilic structure-directing compounds are removed by extraction and/or by thermal decomposition and/or by chemical decomposition.

In an advantageous alternative embodiment for generating the monolithic combinations of substrate (1) and contact elements (2), topographic structuring is implemented for fabricating the contact elements (2) at the same time the continuous pore system is generated. For increasing the area of the pore openings on the surface of the monolithic combinations of substrate (1) and contact elements (2), the latter can be processed with etching methods such as oxygen plasma treatment or reactive ion etching. Tubular contact elements, as illustrated in FIG. 2b, may be produced for example by moulding templates with cylindrical template pores, the pore formation combined with the moulding being implemented in such a way that the structural image processes leading to pore formation are dominated by boundary surface interactions with the template pores.

A feature of an inventive technical device for capillary nanoprinting is that ink can be advanced to the contact elements (2) through the continuous pore systems of the monolithic combinations of substrate (1) and contact elements (2), depending on requirement in each case, either continuously or in phases. For this purpose an actively generated pressure differential is not absolutely necessary within the ink. In fact the substrate (1) can be brought into contact with an ink reservoir, to which substrate (1) is either laterally connected or is in contact with the lower side of the substrate (1) facing away from the contact elements (2). In an advantageous alternative embodiment of the inventive technical device for capillary nanoprinting the side of the substrate (1) facing away from the contact elements (2) is connected to a further porous layer, which is completely or partially soaked with ink and serves as ink reservoir. Said porous layer can completely or partially consist of at least one component, which is selected from paper and/or cellulose and/or cellulose containing materials and/or fibre mats and/or fillings of fibres and/or fillings of beads and/or fillings of not-spherical discrete particles and/or weaves and/or felt and/or electrospun fibre mats and/or fabrics of all kinds and/or sand and/or foams and/or gels such as aerogels or xerogels. In an advantageous alternative embodiment of the inventive technical device for capillary nanoprinting the ink is advanced to the contact elements (2) and the monolithic combinations of substrate (1) and contact elements (2) are refilled purely passively via capillary forces. It is however also possible to integrate additional components into the technical device for capillary nanoprinting, which enable ink to be actively transported to the contact elements (2) by generating an ink flow or pressure differential in the ink. An example of such a further component is a peristaltic pump.

The monolithic combination of substrate (1) and contact elements (2) (possibly in combination with a further porous layer) can be implemented so that this is planar in its entirety. The monolithic combination of substrate (1) and contact elements (2) (possibly in combination with a further porous layer) can be curved likewise in its entirety or at least partially. Furthermore the rigidity of the monolithic combination of substrate (1) and contact elements (2) (possibly in combination with a further porous layer) can be adapted to the technical requirements accordingly. Thus it may be advantageous if the monolithic combination of substrate (1) and contact elements (2) (possibly in combination with a further porous layer) is resilient, since this can then be adapted to possible roughness of the surface to be printed (3) in such a manner that despite the roughness of the surface to be printed (3) all contact elements (2) can touch the surface to be printed (3). So that the adaptability of an inventive technical device for capillary nanoprinting can be adjusted to a rough surface to be printed (3), the monolithic combination of substrate (1) and contact elements (2) (possibly in combination with a further porous layer) can be integrated into a multi-laminated structure. An advantageous alternative embodiment of such a multi-laminated structure contains a thin, more rigid monolithic combination of substrate (1) and contact elements (2), which is in contact with a soft and optionally porous protective layer. While the rigidity of the monolithic combination of substrate (1) and contact elements (2) locally ensures the mechanical stability of the contact elements (2), the soft protective layer permits adjustment to the roughness of the surface to be printed (3), so that contact between contact elements (2) and surface to be printed (3) is improved.

Inventive technical devices for capillary nanoprinting can be realised in various technical alternative embodiments. FIG. 3 by way of example illustrates an embodiment which is configured for continuous rolling operation. The monolithic combination of substrate (1) and contact elements (2) is a component of a roller. As a result of a rotational movement of the roller with the combination of substrate (1) and contact elements (2) a surface (3), which is guided past the roller at a speed adapted to the rotary speed of the roller, can be printed with ink drops (5).

The roller can completely consist of the monolithic combination of substrate (1) and contact elements (2). In this case the substrate (1) is implemented as cylinder, which has the contact elements (2) on its outer surface. In order to supply ink via the substrate (1) to the contact elements (2) on roller structures, which completely consist of monolithic combinations of substrate (1) and contact elements (2), in a continuously or intermittently controlled way, various alternatives for filling said roller structure with ink are conceivable. If the longitudinal axis of said roller structure is horizontal, the roller structure can be supplied with ink completely or partially continuously or during selected time intervals. The roller structure can be supplied with ink, while it rotates at its operating angular velocity about its longitudinal axis, on at least one segment of the roller structure, which does not come into contact with the surface to be printed (3) and/or on at least one segment of the roller structure, which comes into contact with the surface to be printed (3). Said roller structure can be supplied with ink for example by means of drizzling. If the longitudinal axis of said roller structure is vertical, the lower part of the roller structure during the continuous rolling operation can dip into an ink reservoir, while the surface to be printed (3) only comes into contact with the top of the roller structure.

The roller however, apart from the monolithic combination of substrate (1) and contact elements (2), can also contain further components. For example a roller structure beside a cylinder jacket-shaped substrate (1), which forms the outer cylindrical surface of the roller structure and which is equipped with contact elements (2) can contain a roller core made of at least one further component, substrate (1) enclosing said roller core. Furthermore components contained in said roller core can be implemented for their part as cylinder or as cylinder jacket. In an advantageous alternative embodiment the roller core contains at least one component, which consists of at least one further porous layer or which at least partially has at least one further porous layer. Said porous layer can completely or partially consist of at least one component, which is selected from paper and/or cellulose and/or cellulose containing materials and/or fibre mats and/or fillings of fibres and/or fillings of beads and/or fillings of non-spherical discrete particles and/or weaves and/or felt and/or electrospun fibre mats and/or fabrics of all kinds and/or sand and/or foams and/or gels such as aerogels or xerogels. In an advantageous alternative embodiment of the roller structure the cylinder jacket-shaped substrate (1) adjoins the further porous layer in such a manner that ink can arrive on the contact elements (2) from the further porous layer via the substrate (1). An advantageous technical solution for supplying ink to such a roller structure proposes that the further porous layer protrudes at least partially under the cylinder jacket-shaped monolithic combination of substrate (1) and contact elements (2). If the longitudinal axis of the roller structure is horizontal, the protruding part of said further porous layer can be supplied with ink completely or partially continuously or during selected time intervals. The roller structure can be supplied with ink, while it rotates at its operating angular velocity about its longitudinal axis, on at least one segment of the roller structure, which does not come into contact with the surface to be printed (3). Said roller structure can be supplied with ink for example by means of drizzling. If the longitudinal axis of said roller structure is vertical and if the further porous layer protrudes downwards under the monolithic combination of substrate (1) and contact elements (2) implemented as cylinder jacket and outwardly adjoining the further porous layer, said protruding part of the further porous layer during the continuous rolling operation can dip into an ink reservoir present in the lower part of the roller structure.

A further advantageous alternative embodiment of capillary nanoprinting is batch working. In this embodiment the monolithic combination of substrate (1) and contact elements (2) is integrated into a technical device for carrying out capillary nanoprinting, which permits the bringing of contact elements (2) and surface to be printed (3) near each other to be controlled and after the ink had been transferred the increase of the distance between contact elements (2) and surface (3) printed with ink drops (5) to be controlled. Subsequently, a further printing cycle, in which either a further, not yet printed surface (3) is printed with ink or in which a surface already printed with ink (3) is printed on once more, can follow on. To this end the technical device for carrying out capillary nanoprinting can be combined with a device, which positions the surfaces to be printed relative to the monolithic combination of substrate (1) and contact elements (2) or which positions the monolithic combination of substrate (1) and contact elements (2) relative to the surfaces to be printed.

Depending on technical requirements in each case a technical device may be provided for carrying out capillary nanoprinting independently of the proposed operating mode (for instance batch working or continuous rolling operation) with individual advantageous equipment and performance features or with any combinations of advantageous equipment and performance features. Examples of advantageous equipment and performance features, which can also be combined with one another at random, are:

i) Automatic advancing the surface to be printed (3) to the fields of the contact elements (2). In this case the section to be printed of the surface to be printed (3) or however the monolithic combination of substrate (1) and contact elements (2) can be positioned in such a way that the desired region of the surface (3) is printed within a printing cycle. Likewise it is conceivable that the surface to be printed (3) is present in the form of discrete sections or discrete parts. In this case either the discrete sections or parts (3) can be positioned automatically in such a way that these can be brought into contact with the contact elements (2). This can be achieved for example by means of a production line-type system. Of course alternative embodiments, which envisage the positioning not of the surfaces to be printed (3), but of the monolithic combination of substrate (1) and contact elements (2), are also conceivable.
ii) a device to control the atmosphere, in which the method of capillary nanoprinting is carried out. For example it can be advantageous to be able to adjust the air humidity in a controlled manner during capillary nanoprinting or to carry out capillary nanoprinting under an inert gas atmosphere.
iii) the design of the technical device for carrying out capillary nanoprinting in such a manner that various monolithic combinations of substrate (1) and contact elements (2) can be easily substituted against one another.
iv) The possibility of carrying out cleaning cycles for removing ink residues and other contamination, by for example immersing the monolithic combinations of substrate (1) and contact elements (2) as well as other components of the technical device for carrying out capillary nanoprinting in cleaning tanks or by conducting cleaning fluids (gas or liquid) through the components, to be cleaned, of the technical device for carrying out capillary nanoprinting.
v) A system for precise command and control of bringing the contact elements (2) and the surface to be printed (3) near each other as well as for precise command and control of the separation of the contact elements (2) and the printed surface (3) from one another. In an advantageous alternative embodiment of this command and control system the distance between the contact elements (2) and surface to be printed (3) can be adjusted with an accuracy of preferably better than 30 nm, particularly preferably better than 10 nm and most preferably better than 2 nm. Furthermore it is advantageous if the bringing near and separation speeds can be adjusted with high precision, preferably with a precision better than 1 μm per second, particularly preferably better than 100 nm per second and most preferably better than 10 nm per second. In an advantageous alternative embodiment of technical devices for carrying out capillary nanoprinting, bringing the contact elements (2) near to the surface to be printed (3) can be stopped as soon as the capillary bridges consisting of ink (4) are formed between the contact elements (2) and the surface to be printed (3). This kind of contact can be made for example by detecting the force necessary for bringing the elements and surface near each other, when an increase of this force during further converging indicates that contact has been made. It is likewise conceivable that when contact is made this is indicated by the closing of electrical contacts between the monolithic combination of substrate (1) and contact elements (2) as well as the surface to be printed (3).
vi) In an advantageous alternative embodiment, technical devices for carrying out capillary nanoprinting have means, which alert when contact is made between contact elements (2) and surface to be printed (3). An advantageous alternative embodiment of a device, which alerts when contact between contact elements (2) and surface to be printed (3) has been made, is based on the creation of an electrical contact between contact elements (2) and surface to be printed (3). An exemplary embodiment proposes the use of monolithic combinations of substrate (1) and contact elements (2), which have electrical conductivity at least partially. Such conductivity for example can be achieved by coating at least parts of monolithic combinations of substrate (1) and contact elements (2) with conductive material, by depositing conductive material into the pores of the monolithic combinations of substrate (1) and contact elements (2) at least in parts of the monolithic combinations of substrate (1) and contact elements (2), or by using monolithic combinations of substrate (1) and contact elements (2), which contain at least in parts at least one electrically conductive material. Furthermore the surface to be printed (3) can be coated at least partially with conductive material in such a manner that conductive regions of the monolithic combinations of substrate (1) and contact elements (2) as well as conductive regions of the surface to be printed (3) create electrically conductive contact when contact is made between monolithic combination of substrate (1) and contact elements (2) as well as the surface to be printed (3).
vii) In an advantageous alternative embodiment technical devices for carrying out capillary nanoprinting have flexible suspension brackets for the monolithic combinations of substrate (1) and contact elements (2) or for the surface to be printed (3). Such flexible suspension brackets for the monolithic combinations of substrate (1) and contact elements (2) or for the surfaces to be printed (3) solve the technical problem that due to imprecise coplanar adaptation of the monolithic combinations of substrate (1) and contact elements (2) as well as the surface to be printed (3) to each other, contact between contact elements (2) and surface to be printed (3) is incorrectly formed.
viii) A further advantageous equipment and performance property of the technical device for carrying out capillary nanoprinting can be the provision of an elastic layer, which is brought into contact with the monolithic combination of substrate (1) and contact elements (2) on the side of the substrate (1) facing away from the contact elements (2). Coplanar adaptation of the monolithic combination of substrate (1) and contact elements (2) to the surface to be printed (3), just as adaptation of the monolithic combination of substrate (1) and contact elements (2) to roughnesses on the surface to be printed (3), can then be implemented by elastic deformation of said elastic layer.
ix) A further advantageous equipment and performance property of technical devices for carrying out capillary nanoprinting is the possibility, during capillary nanoprinting, of being able to adjust the temperature either of the entire unit consisting of ink storage and delivery system, monolithic combination of substrate (1) and contact elements (2) as well as surface to be printed (3) or parts thereof. Particularly advantageous here are alternative embodiments, which permit the adjustment of specific temperatures at least in parts of the ink storage and delivery system, monolithic combination of substrate (1) and contact elements (2) as well as surface to be printed (3) in each case independently, so that at least in parts of the technical devices for carrying out capillary nanoprinting temperature differences may be produced in a controlled way. Further advantageous is the possibility of creating, at least in parts, temperature differences in each case within monolithic combinations of substrate (1) and contact elements (2) and/or surface to be printed (3). Suitable components for heating and/or cooling, which can be integrated into technical devices for carrying out capillary nanoprinting, are heating cartridges or Peltier elements for example.
x) A further advantageous equipment and performance property of devices for carrying out capillary nanoprinting is the possibility of carrying out capillary nanoprinting in the presence of electric fields. Exemplary advantages are the generation of specific surface loads on the walls of the continuous pore system of the monolithic combinations of substrate (1) and contact elements (2), control of ink transport by means of electric fields or the combination of capillary nanoprinting with electro-chemical processes. Advantageous embodiments of electric fields at least in parts of devices for carrying out capillary nanoprinting include the generation of electric fields between monolithic combination of substrate (1) and contact elements (2) as well as surface to be printed (3). It may also be advantageous to apply an electric field within the monolithic combination of substrate (1) and contact elements (2) and/or within the surface to be printed (3), whereby this electric field can possess any orientations, which however are selected in a controlled manner based on the technical application requirements. A particularly advantageous alternative embodiment of capillary nanoprinting includes controlling the shape of the printed ink drops (5) on the printed surface (3) by exploiting electrowetting phenomena.
xi) A further advantageous equipment and performance property of devices for carrying out capillary nanoprinting is the possibility of carrying out capillary nanoprinting in the presence of magnetic fields.

Capillary nanoprinting in each case at the positions of the contact elements (2) leads to the deposition of ink drops (5) on the surface to be printed (3). In this case the ink (4) is transferred from the contact elements filled with ink (2) to the surface to be printed (3) via capillary bridges consisting of ink (4) (see FIG. 1). Dependent on the way that the capillary bridges consisting of ink (4) breaks when the contact elements (2) separate from the printed surface (3), the ink drops (5) deposited on the printed surface (3) can have substantially lesser dimensions than the contact elements (2). A typical example of inventive technical devices for carrying out capillary nanoprinting have hexagonal arrays of contact elements (2) with diameters of ˜60 nm, nearest-neighbour distances of ˜100 nm and surface densities of ˜130 contact elements (2) per μm² over a total area of 9 cm². The use of this exemplary device for carrying out capillary nanoprinting thus leads to the deposition of discrete ink drops (5) with volumes down to 10 zeptolitres, which over a surface of 9 cm² form a hexagonal array with nearest neighbour distances of ˜100 nm and surface densities of ˜130 ink drops (5) per μm². By means of the various alternative embodiments of capillary nanoprinting a broad spectrum of different inks can be printed. In principle any free-flowing liquid consisting of a pure material or from a mixture of several materials and/or components, whether a melt, a mixture, a solution, an emulsion, a suspension or an ionic liquid, can be printed. It is conceivable that the ink incurs special interactions with the face of the surface to be printed (3) or that the ink (4) produces specific chemical reactions on the face of the surface to be printed (3) and that in this way the ink drops (5) form in a controlled manner. Inks (4), which can be printed using at least one embodiment of capillary nanoprinting, can be specially selected or form any combinations consisting of:

i) Liquids, melts, mixtures, solutions, emulsions, suspensions or ionic liquids, which contain at least nanoparticles with diameters from 1 nm to 500 nm, which in turn have at least one or any combination of the following properties: the nanoparticles consist of semiconductors and/or the nanoparticles consist of metal and/or the nanoparticles consist of oxide and/or the nanoparticles consist of organic ligands on an inorganic core and/or the nanoparticles consist of any combinations of semiconductors, metals, oxides and organic ligands and/or the nanoparticles consist of several layers of different materials selected from semiconductors, metals, oxides and organic ligands and/or the nanoparticles are magnetic or magnetisable and/or the nanoparticles are ferroelectric and/or the nanoparticles show fluorescence and/or the nanoparticles show light emission in the wavelength range from 100 nm to 10 μm and/or the nanoparticles show plasmon absorption and/or ligands bound to the nanoparticles or compounds present in direct proximity to the nano-particle surface show surface-enhanced raman scattering (SERS) and/or the nanoparticles show upconversion of electromagnetic radiation and/or the nanoparticles show downconversion of electromagnetic radiation and/or the nanoparticles show spin polarisation or spin polarisability.
ii) liquids, melts, mixtures, solutions, emulsions, suspensions or ionic liquids, which contain at least one polymeric material or any combinations of polymeric materials, whereby said polymeric materials can be selected inter alia from
organic polymers such as poly(p-xylene), polyacrylamide, polyimides, polyesters, polyolefins, polystyrenes, polycarbonates, polyamides, polyethers, polyphenyls, polysilanes, polysiloxanes, polybenzimidazoles, polybenzthiazoles, polyoxazoles, polysulfides, polyester amides, polyarylene vinylenes, polylactides, polyetherketones, polyurethanes, polysulfones, inorganic and organic hybrid polymers, polyacrylates, silicones, fully aromatic co-polyesters, poly N vinylpyrrolidone, polyhydroxyethyl methacrylate, polymethyl methacrylate, polyethylene teraphthalate, polybutylene teraphthate, polymethacrylic nitrile, polyacrylic nitrile, polyvinyl acetate, neoprene, Buna N, polybutadiene, polyethylene,
fluorine-containing polymers such as polyvinylidene fluoride, polytrifluorethylene, polytetrafluoroethylene, polyhexaflouropropylene,
biological polymers such as polysaccharides, cellulose (modified or non-modified), alginates, polypeptides, collages, DNA, RNA,
polymers which are composed of at least two different repeating units preferably in the form of statistical copolymers, block copolymers, graft copolymers, dendrimers,
copolymers, which contain fluorine-containing comonomers, preferably fluorine-containing comonomers which are derived from fluoroethylene, difluoroethylene, tri fluoroethylene, tetrafluoroethylene or hexafluoropropylene,
dendrimers
conductive and semiconducting polymers.
   iii) liquids, melts, mixtures, solutions, emulsions, suspensions or ionic liquids, which contain at least one monomer or any combinations of monomers of polymeric materials, whereby said monomers can be selected inter alia from monomers for
organic polymers such as poly(p-xylene), polyacrylamide, polyimides, polyesters, polyolefins, polystyrenes, polycarbonates, polyamides, polyethers, polyphenyls, polysilanes, polysiloxanes, polybenzimidazoles, polybenzthiazoles, polyoxazoles, polysulfides, polyester amides, polyarylene vinylenes, polylactides, polyetherketones, polyurethanes, polysulfones, inorganic and organic hybrid polymers, polyacrylates, silicones, fully aromatic co-polyesters, poly N vinylpyrrolidone, polyhydroxyethyl methacrylate, polymethyl methacrylate, polyethylene teraphthalate, polybutylene terephthalate, polymethacrylic nitrile, polyacrylic nitrile, polyvinyl acetate, neoprene, Buna N, polybutadiene, polyethylene,
fluorine-containing polymers such as polyvinylidene fluoride, polytrifluorethylene, polytetrafluoroethylene, polyhexaflouropropylene,
biological polymers such as polysaccharides, cellulose (modified or non-modified), alginates, polypeptides, collages, DNA, RNA,
dendrimers,
conductive and semiconducting polymers.
   iv) Liquids, melts, mixtures, solutions, emulsions or suspensions, which have at least one ionic liquid.
   v) Liquids, melts, mixtures, solutions, emulsions, suspensions or ionic liquids, which have at least one photocross-linkable component.
   vi) Liquids, melts, mixtures, solutions, emulsions, suspensions or ionic liquids, which have at least one thermally cross-linkable component.
   vii) Liquids, melts, mixtures, solutions, emulsions, suspensions or ionic liquids, which contain at least one acid.
   viii) Liquids, melts, mixtures, solutions, emulsions, suspensions or ionic liquids, which contain at least one base.
   ix) Liquids, melts, mixtures, solutions, emulsions, suspensions or ionic liquids, which contain at least one compound, which can bond to the surface to be printed via an anchor group, whereby said anchor group can be selected inter alia from thiol groups, silane groups, halogenosilane groups, alkosilane groups, phosphonate groups and 1-alkyl groups.
   x) Liquids, melts, mixtures, solutions, emulsions, suspensions or ionic liquids, which contain at least one component, which can form SAMs (“self assembled monolayers”) on the surface to be printed (3).
   xi) Liquids, melts, mixtures, solutions, emulsions, suspensions or ionic liquids, which contain at least one component, which contains at least two functional groups, whereby preferably one of said functional groups can bond onto surface (3) and at least one further of said functional groups permits the immobilisation of further compounds and/or chemical functionalisation and whereby said groups are preferably selected from alkyl groups, derivatives of alkyl groups, alkenyl groups, alkinyl groups, phenyl groups, derivatives of phenyl groups, halogen alkyl groups, halogen aryl groups, hydroxyl groups, carbonyl groups, aldehyde groups, carboxyl groups, ketol groups, carbonate groups, ether groups, ester groups, alkoxy groups, peroxo groups, acetal groups, semi acetal groups, amino groups, amido groups, imino groups, imido groups, azido groups, azo groups, cyanate groups, nitrate groups, nitrilo groups, nitrito groups, nitro groups, nitroso groups, pyirdino groups, thiol groups, sulfide groups, disulfide groups, sulfoxide groups, sulphonyl groups, sulfino groups, sulfo groups, thiocyanate groups, sulfate groups, sulfonate groups, phosphine groups, phosphonate groups and/or phosphate groups.
   xii) Sol-gel formulations, preferably sol-gel formulations which contain at least one of the following components or any combinations of the following components: precursor compounds for silicon oxide, precursor compounds for titanium oxide, precursor compounds for aluminium oxide, precursor compounds for tantalum oxide, precursor compounds for oxides of semiconductors or metals, precursor compounds for amorphous or partially crystalline or completely crystalline carbon materials, surfactants, amphiphile block copolymers.
   xiii) Liquids, melts, mixtures, solutions, emulsions, suspensions or ionic liquids, which contain at least one precursor compound for a metal, to be selected inter alia from gold, silver, platinum, palladium, tungsten, copper, titanium, aluminium, tantalum.
   xiv) Liquids, melts, mixtures, solutions, emulsions, suspensions or ionic liquids, which contain at least one precursor compound for inorganic oxides, whereby said inorganic oxides can be selected inter alia from silicon oxide, titanium oxide, aluminium oxide and tantalum oxide.
   xv) Liquids, melts, mixtures, solutions, emulsions, suspensions or ionic liquids, which contain at least one precursor compound for amorphous or partially crystalline or completely crystalline carbon materials.
   xvi) Liquids, melts, mixtures, solutions, emulsions, suspensions or ionic liquids, which contain affinity tags and/or antibodies and/or antigens and/or DNA and/or RNA.
   xvii) Liquids, melts, mixtures, solutions, emulsions, suspensions or ionic liquids, which can be reversibly and/or irreversibly changed in their liquid and/or solidified state by effect of electromagnetic radiation and/or electric fields and/or by magnetic fields and/or by effect of phonons in at least one of their properties.

As a result of capillary nanoprinting ink (5) applied on a printed surface (3) can be solidified inter alia by at least one of the following methods or any combinations of the following methods:

i) crystallisation of at least one crystallisable component contained in the ink.
ii) glazing of at least one glass-forming component contained in the ink.
iii) evaporation of at least one volatile component contained in the ink.
iv) photo cross-linking of at least one photo cross-linkable component contained in the ink.
v) thermal cross-linking of at least one thermally cross-linkable component contained in the ink.
vi) polymerisation of at least one polymerisable component contained in the ink.
vii) chemisorption and/or physisorption of at least one component (3) contained in the ink onto the surface to be printed.

The actual process of capillary nanoprinting can be implemented in various alternative embodiments, which are advantageous depending on the technical application. Exemplary alternative embodiments are described below.

Liquid on solid capillary nanoprinting (LOS capillary nanoprinting) can be combined with any other alternative embodiments of capillary nanoprinting. LOS capillary nanoprinting is carried out in such a manner that a vacuum or a gaseous phase exists between the monolithic combination, soaked in ink (4), of substrate (1) and contact elements (2) as well as the surface to be printed (3). Said gaseous phase can concern air with a specific humidity for example. Depending on the technical requirements said gaseous phase can also be enriched with specific gases or any combination of specific gases, or the gaseous phase can consist completely of specific gases or any combinations of specific gases. Said gases, which can form the gaseous phase either as pure material or in the form of any combinations, may be selected inter alia from water, oxygen, hydrogen, argon, nitrogen, helium, synthesis gas, alkanes, alkenes, alkines, at least partially aliphatic and/or aromatic and/or halogenated hydrocarbons, ethers, esters, silanes, and/or siloxanes. Advantageous alternative embodiments of LOS capillary nanoprinting can envisage the use of an inert gaseous phase or however the use of a reactive gaseous phase. A critical step in the method of LOS capillary nanoprinting (see FIG. 1) is the formation of the capillary bridges consisting of ink (4) between the contact elements (2) and the surface to be printed (3) while the monolithic combination of substrate (1) and contact elements (2) as well as the surface to be printed (3) are brought near to each other. A second critical step is the tearing apart of said capillary bridges consisting of ink (4) while the monolithic combination of substrate (1) and contact elements (2) as well as the surface to be printed (3) are separated from one another. In this case a part of the volumes of the capillary bridges consisting of ink (4) remains behind on the surface to be printed (3) as ink drops (5). The size of the ink drops (5) deposited in this way on the surface to be printed (3) can be adjusted inter alia by means of the following parameters: angle of contact between ink (4) and material of the contact elements (2); angle of contact between ink (4) and surface to be printed (3); curvature of contact geometry of the contact elements (2); duration of the contact between contact elements (2) and surface to be printed (3); speed, at which the monolithic combination of substrate (1) and contact elements (2) as well as the printed surface (3) are separated from one another after the end of the contact period.

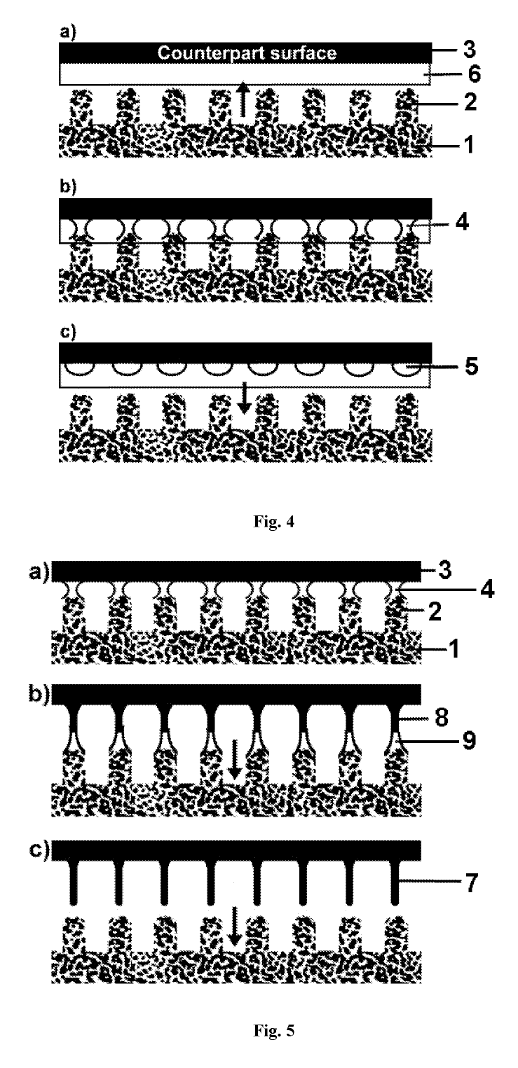

Liquid in liquid capillary nanoprinting (LIL capillary nanoprinting) is illustrated by way of example in FIG. 4 and corresponds to LOS capillary nanoprinting described above, whereby however the surface to be printed (3) is coated with a matrix liquid (6). LIL capillary nanoprinting can be combined with any other alternative embodiments of capillary nanoprinting. The matrix liquid (6) surrounds the ink drops (5) deposited according to LIL capillary nanoprinting on the printed surface (3) except on the contact area between the ink drips (5) deposited on the surface to be printed (3) and the printed surface (3). LIL capillary nanoprinting can be carried out with any ink (4), if the latter possesses a greater affinity to the contact elements (2) and the surface to be printed (3) than the matrix liquid (6) covering the surface to be printed (3). Conversely any matrix liquid (6) can be used, as long as the matrix liquid (6) possesses a lesser affinity to the contact elements (2) and the surface to be printed (3) than the ink (4). The advantage of LIL capillary nanoprinting is that either selectively the ink drops deposited on the surface to be printed (5) can be solidified or selectively the matrix liquid (6) or both the ink drops (5) deposited on the surface to be printed (3) and also the matrix liquid (6) can be solidified. The solidification of the matrix liquid (6) can be induced for example by crystallisation of at least one crytallisable component contained therein and/or by glazing at least one glass-forming component contained therein and/or by evaporation of at least one volatile component contained therein and/or by photo cross-linking of at least one photocross-linkable component contained therein and/or by thermal cross-linking of at least one thermally cross-linkable component contained therein and/or by polymerisation of at least one polymerisable component contained therein.

In an advantageous alternative embodiment of LIL capillary nanoprinting the matrix liquid (6) is selected in such a way that this in its liquid and/or in its solidified state is transparent for electromagnetic radiation in selected wavelength ranges. In another advantageous alternative embodiment of LIL capillary nanoprinting the matrix liquid (6) is selected in such a way that this in its liquid and/or in its solidified state can be penetrated by electric and/or magnetic fields. In a further advantageous alternative embodiment of LIL capillary nanoprinting the matrix liquid (6) is selected in such a way that this in its liquid and/or in its solidified state can be reversibly or irreversibly changed by effect of electromagnetic radiation and/or of electric fields and/or by magnetic fields in at least one of its properties. Said preferred alternative embodiments can be arbitrarily combined with one another.

LIL capillary nanoprinting therefore possesses inter alia the following advantages: i) As a result of selective solidification of the matrix liquid (6) a monolith may be produced from the solidified matrix liquid (6), whose contact area with the printed surface (3), after separating from the printed surface (3) and removal of the still liquid ink drops (5), originally deposited on the printed surface (3), has cavities at the positions of the ink drops (5), whereby surface densities of more than 130 cavities per μm² can be achieved. ii) By simultaneous or consecutive solidification of the matrix liquid (6) and the printed ink drops (5) a monolith may be produced from the solidified matrix liquid (6), whose contact area with the printed surface (3) after removing from the printed surface (3) has arrays of solidified ink drops (5), whereby surface densities of more than 130 solidified ink drops per μm² can be achieved. iii) Selective solidification of the matrix liquid (6) in such a manner that this in its solidified form remains in adhesive contact with the printed surface (3), leads to encapsulation of the printed liquid ink drops (5). Thus for example over areas of several cm² arrays of encapsulated liquid ink drops (5) can be produced with volumes down to a few 10 zeptolitres with surface densities of more than 130 ink drops per μm². iv) Simultaneous or consecutive solidification of the matrix liquid (6) and the printed ink drops (5) in such a manner that matrix liquid (6) in its solidified form remains in adhesive contact with the printed surface (3), leads to encapsulation of the printed solidified ink drops (5). Thus for example arrays of solidified ink drops (5) encapsulated over areas of several cm² can be produced with volumes down to a few 10 zeptolitres with surface densities of more than 130 ink drops per μm².

It is conceivable that LIL capillary nanoprinting is combined with diffusion processes induced in a controlled way. For example it is conceivable that at least one mobile component of the ink consisting of liquid or solidified drops (5) is diffused into the liquid or solidified matrix liquid (6). Conversely it is equally conceivable that at least one mobile component of the liquid or solidified matrix liquid (6) is diffused into the liquid or solidified drops (5) of the ink. Both aforementioned forms of material transfer can also be combined. At the same time or at another time or successively in each case one or more substances from the liquid or solidified matrix liquid (6) can be diffused into the liquid or solidified ink drops (5) and from the liquid or solidified ink drops (5) into the liquid or solidified matrix liquid (6). Such transport processes can also be exploited for additional structural image processes. Thus for example either the sizes of the drops (5) can be changed by using the Kirkendall effect after the actual capillary nanoprinting or cavities can be produced in the solidified ink drops (5) and/or in the solidified matrix liquid (6) in a controlled way.

A further advantageous alternative embodiment of capillary nanoprinting is electro-chemically modulated capillary nanoprinting (EM capillary nanoprinting), i.e. capillary nanoprinting under effect of electric fields. Here one or more electrodes can be attached to the side of the substrate (1) facing away from the contact elements (2) and/or in and/or below the surface to be printed (3). It is equally conceivable that the monolithic combination of substrate (1) and contact elements (2) and/or the surface to be printed (3) itself consists of conductive material and acts as electrodes. EM capillary nanoprinting inter alia enables the deposition of ink drops to be electro-chemically controlled as this has already been shown for depositing liquid drops from individual cantilever tips.^{xxxii, xxxiii} Moreover the behaviour of ink drops (5) deposited on a surface (3), in particular the angle of contact between ink and surface (3) can be controlled by electrical wetting phenomena or by phenomena in connection with electrical wetting on dielectrics. These two phenomena are already known for liquid drops on conductive or dielectric surfaces.^{xxxiv, xxxv}

High temperature capillary nanoprinting (HT capillary nanoprinting) and low temperature capillary nanoprinting (LT capillary nanoprinting) include carrying out the capillary nanoprinting method either completely or partially at temperatures above or below ambient temperature. Also HT/LT capillary nanoprinting can be combined with any other alternative embodiments of capillary nanoprinting. HT/LT capillary nanoprinting can be carried out for example in such a manner that an inventive technical device for carrying out capillary nanoprinting is completely or partially brought to a temperature different from ambient temperature. For example it is conceivable that the monolithic combination of substrate (1) and contact elements (2) is completely or partially brought to a temperature selected in accordance with the technical requirements. Also the surface to be printed (3) can be brought to a temperature selected in accordance with the technical requirements. HT/LT capillary nanoprinting likewise can be carried out in the presence of any temperature differences, which are produced at least within parts of the technical device for carrying out capillary nanoprinting. Said temperature differences can be produced for instance within the monolithic combination of substrate (1) and contact elements (2) or within the surface to be printed (3) or between the monolithic combination of substrate (1) and contact elements (2) and the surface to be printed (3). HT/LT capillary nanoprinting can be carried out in the following exemplary alternative embodiments:

i) If the technical device for carrying out capillary nanoprinting is completely or partially cooled to temperatures below ambient temperature, ink can be printed, which would be gaseous at ambient temperature or which contains at least one component, which would be gaseous at ambient temperature. If this alternative embodiment of LT capillary nanoprinting is combined with LIL capillary nanoprinting, ink drops (5) encapsulated after solidification of the matrix liquid (6) and heating of fields, which contain at least one gaseous component, can be obtained. In this way for example fields of encapsulated volumes, in which a pressure lying above ambient pressure prevails in each case, may be produced.
ii) if the technical device for carrying out capillary nanoprinting is completely or partially heated to temperatures above ambient temperature, ink which would be solidified at ambient temperature or containing at least one component which would be solidified at ambient temperature, can be printed.
iii) in a further embodiment of HT capillary nanoprinting the surface to be printed (3) is heated to a temperature, which is higher than the temperature of the monolithic combination of substrate (1) and contact elements (2). If the printed ink contains a component, which is liquid at the temperature of the monolithic combination of substrate (1) and contact elements (2) or remains a component of the ink, which however evaporates or decomposes or produces a specific chemical reaction at the temperature of the surface to be printed (3), this can be exploited, in order to produce fields consisting of drops or particles of evaporation and/or decomposition and/or reaction products of the ink on the surface to be printed (3).
iv) In a further embodiment of HT/LT capillary nanoprinting the surface to be printed (3) is brought to a temperature, which lies below the temperature of the monolithic combination of substrate (1) and contact elements (2). If the printed ink contains at least one component, which is solidified at the temperature of the surface to be printed (3), the ink deposited on the surface to be printed (3) can be solidified at the moment of deposition or at a point in time after the moment of deposition.

With the inventive device for carrying out capillary nanoprinting, as illustrated by way of example in FIG. 5, structures consisting of ink solidified in the course of capillary nanoprinting, which extend in a direction perpendicular to the surface of the surface to be printed (3) can also be printed. For example fields of wires (7) perpendicular to the printed surface can be produced by means of capillary nanoprinting (3). The wires (7) can contain inter alia at least one component, which is selected from

i) polymeric materials or any combinations of polymeric materials, whereby said polymeric materials can be selected inter alia from
organic polymers such as poly(p-xylenes), polyacrylamide, polyimides, polyesters, polyolefins, polystyrenes, polycarbonates, polyamides, polyethers, polyphenyls, polysilanes, polysiloxanes, polybenzimidazoles, polybenzthiazoles, polyoxazoles, polysulfides, polyester amides, polyarylene vinylenes, polylactides, polyetherketones, polyurethanes, polysulfones, inorganic and organic hybrid polymers, polyacrylates, silicones, fully aromatic co-polyesters, poly N vinylpyrrolidone, polyhydroxyethyl methacrylate, polymethyl methacrylate, polyethylene teraphthalate, polybutylene teraphthate, polymethacrylic nitrile, polyacrylic nitrile, polyvinyl acetate, neoprene, Buna N, polybutadiene, polyethylene,
fluorine-containing polymers such as polyvinylidene fluoride, polytrifluorethylene, polytetrafluoroethylene, polyhexaflouropropylene,
biological polymers such as polysaccharides, cellulose (modified or non-modified), alginates, polypeptides, collages, DNA, RNA,
polymers, which are composed of at least two different repeating units, preferably in the form of statistical copolymers, block copolymers, graft copolymers, dendrimers,
copolymers, which contain fluorine-containing comonomers, preferably fluorine-containing comonomers which are derived from fluoroethylene, difluoroethylene, tri fluoroethylene, tetrafluoroethylene or hexafluoropropylene,
dendrimers,
   ii) conductive and/or semiconducting polymers,
   iii) salts,
   iv) metals such as gold, silver, platinum, palladium, copper, tantalum, tungsten, aluminium,
   v) inorganic oxides such as silicon oxide, titanium oxide, aluminium oxide, tantalum oxide,
   vi) amorphous or partially crystalline or completely crystalline carbon materials, vii) semiconductors, preferably elemental semiconductors as for example silicon and germanium or compound semiconductors as for example gallium arsenide.

Preferably the wires (7) produced by means of capillary nanoprinting have a diameter of less than 500 nm, particularly preferably less than 100 nm and most preferably less than 30 nm. The length of the wires (7) is preferably greater than 500 nm, particularly preferably greater than 1 μm and most preferably greater than 5 μm. In an exemplary embodiment the fields of wires (7) can have surface densities of more than 130 wires per μm² and cover an area of more than 9 cm², whereby the wires possess diameters of 50 nm and lengths of more than 2 μm. Polymeric wire fields are produced by capillary nanoprinting in such a manner that, after the capillary bridges consisting of ink (4) have formed between the contact elements (2) and the surface to be printed (3), the contact elements (2) and the printed surface (3) are separated from one another in such a manner that the capillary bridges consisting of ink (4) do not tear. Instead by stretching the capillary bridges consisting of ink (4) and/or by flow of ink from the contact elements (2) into the capillary bridges consisting of ink (4), the length of the capillary bridges consisting of ink (4) is adapted to the increasing distance between contact elements (2) and the printed surface (3). At the same time or at a deferred time, in an advantageous alternative embodiment, the solidification of the ink is induced in the capillary bridges, whereby the solidification front starting from the boundary surface between printed surface (3) and the capillary bridges consisting of ink (4) are propagated by the printed surface (3) along the capillary bridges consisting of ink (4). Therefore the length of the solidified segments (8) of the capillary bridges consisting of ink increases, while still liquid ink (9) is present between the solidification fronts and the contact elements (2). The solidification of the ink in the capillary bridges (4) between printed surface (3) and solidification front can for example be implemented by cooling the ink in the capillary bridges (4) in the presence of a temperature difference between contact elements (2) and printed surface (3). Likewise solidification of the capillary bridges consisting of ink (4) between printed surface (3) and solidification front is possible by electro-chemical reactions in the capillary bridge, for instance polymerisation or electro-chemical deposition of metals. The contact elements (2) can be separated from the wires (7) obtained in this way, arranged perpendicularly on the printed surface (3) inter alia by temporarily or permanently stopping the supply of ink to the contact elements (2) or by separating contact elements (2) and printed surface on (3) at greater speed.

A further advantageous alternative embodiment to solidify the wires (7) is based on the fact that the capillary bridges consisting of ink (4) contain at least one photo cross-linkable component and/or at least one thermally cross-linkable component and/or at least one polymerisable component so that the capillary bridges consisting of ink (4) can be soldified as a whole by photo cross-linking and/or thermal cross-linking and/or polymerisation.

Fields of wires produced by capillary nanoprinting can contain wires, which are arranged perpendicularly on surface (3). In an advantageous alternative embodiment capillary nanoprinting can be used, in order to produce fields of wires (7), whose longitudinal axis with the printed surface (3) includes an angle of less than 90°, preferably less than 70°. For this purpose during the separation of the contact elements (2) from the printed surface (3) the separation movement in the perpendicular direction is combined with a transverse movement between the monolithic combination of substrate (1) and contact elements (2) as well as the printed surface (3) against each other, i.e. a shearing movement between the monolithic combination of substrate (1) and contact elements (2) as well as the printed surface (3).

Example of a functional material which can be formed into nanowires by means of capillary nanoprinting, is ferroelectrical polymer poly(vinylidene fluoride stat trifluorethylene) P(VDF ran TrFE), which as melt consisting of contact elements (2) heated above the fusion point of P(VDF ran TrFE) is deposited on a surface to be printed (3). Likewise electro-chemical methods can be adapted for producing wire arrays by means of EM capillary nanoprinting, which have been demonstrated to date in a serial way between individual cantilever tips or micropipettes and areas present among them. Examples of this are the generation of metal nanowires as well as electrical polymerisation of conductive polymers.^{xxxvi-xxxviii} In particular ITO glass, metal surfaces or carbon materials are suitable as surfaces to be printed (3) for combinations of HT capillary nanoprinting and EM capillary nanoprinting.

The inventive technical device for carrying out capillary nanoprinting as well as the inventive method of capillary nanoprinting solve a series of problems, which cannot be achieved according to the prior art.

As a result of providing the inventive device the inventors have succeeded in making a device and a method available in which fields of ink drops can be obtained, which overcome the disadvantages of the prior art in a surprising way.

In detail the method of depositing ink by capillary nanoprinting can be flexibly controlled by a variety of process parameters, for instance the purposeful design of the capillary bridges consisting of ink (4) between contact elements (2) and surface to be printed (3) and purposeful control of breaking said capillary bridges, so that sizes, morphologies and chemical quality of the deposited ink drops can be flexibly adjusted.

Capillary nanoprinting also permits flexible combination with electric fields, electro-chemical modulation and/or temperature differences in order to control the deposition of the ink, as well as to supply additional ink into the contact zone between contact elements (2) and surface to be printed (3), for instance in order to produce wires (7). Stamp-based contact-lithographic methods do not have these advantages as a result of their intrinsic limitation to the transfer of thinner layers, adsorbed on the stamp surface. In particular it is not possible with the aid of stamp-based contact-lithographic methods to produce structures other than two-dimensional thin layers on the printed surface. This limitation is overcome in an advantageous way by capillary nanoprinting.

The creation of wide nanoscale dot or drop patterns, which preferably have nearest-neighbour-distances of less than one micrometre with a total area of preferably more than one square millimetre, is not generally achieved according to the prior art. Typically the number of printed dots per mm² amounts to a few 100 in accordance with the prior art. A marginal increase of this number by an order of magnitude at most can be achieved if the stamp is subject to a transverse movement in each case by means of complex technical devices between sequential contacts with the surface to be printed, i.e. the printing process is carried out partially serially. xi′ This requires the disadvantageous necessity to precisely adjust the relative positioning of the stamp between two contacts in a technically complex way by means of devices otherwise used for scanning probe microscopy. It is further disadvantageous that at least to guarantee consistent print quality between the contacts new ink must be adsorbed every time and as a result cycle times of several minutes, which are disadvantageous for technical use, are necessary for each contact. By contrast 5333333 dots per mm² in the form of denser hexagonal fields can be produced in parallel on a surface to be printed of several square centimetres via a single contact in a representative alternative embodiment of capillary nanoprinting.

Exemplary uses of capillary nanoprinting are described below:

An exemplary use of capillary nanoprinting is the coating of surfaces with fields of micro to mesoporous nanoparticles with volumes, which are preferably less than one picolitre, particularly preferably less than one ferntolitre, most preferably less than one attolitre and the continuous or discrete pore structures have pore diameters of less than 50 nm, preferably less than 20 nm, particularly preferably less 2 nm. Capillary nanoprinting solves the problem that deposition of micro to mesoporous nanoparticles on surfaces consisting of solution^{xxxix, xi} requires said micro to mesoporous nanoparticles to be fixed on said surface via complex chemical reactions, while controlled spatial positioning of said micro to mesoporous nanoparticles cannot be achieved. By means of capillary nanoprinting fields of nanoparticles consisting of zeolite, MCM^{xli} and SBA^{xlii} as well as generally micro to mesoporous nanoparticles consisting of inorganic oxides such as silicon oxide, titanium oxide, aluminium oxide or tantalum oxide, metals and carbon materials or MOFs (“metal organic frameworks”) can be produced on surfaces to be printed (3). Said nanoparticles in this case can have internal pore structures^{xliii-xlv}, which contain parallel-arranged cylindrical pores or three-dimensional continuous pore systems, as for instance cubic pore systems for example. In a preferred alternative embodiment of capillary nanoprinting for generating the desired micro to mesoporous nano-particles, suitable sol-gel solutions are printed. In a particularly preferred alternative embodiment EM capillary nanoprinting is used, in order to control the orientation of the micro/mesopores relative to the printed surface (3) under the influence of electric fields during capillary nanoprinting.

A further exemplary use of capillary nanoprinting is nano-drop lithography, which employs the use of fields, produced by means of capillary nanoprinting, of ink drops (5) for further lithographic and/or topographic structuring of the printed surface (3).

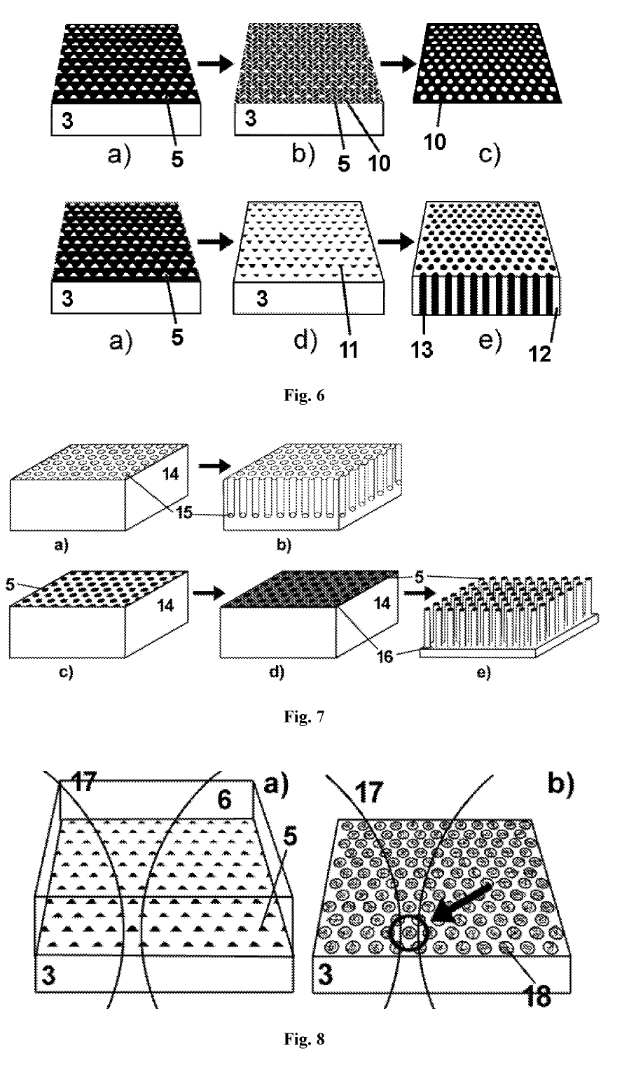

Advantage of combining capillary nanoprinting and nano-drop lithography is that process steps necessary according to the prior art for lithographic and/or topographic structuring of surfaces (3) are no longer required. Thus for example lithographic methods such as block copolymer lithography, in the course of which masks or templates which are first produced at great expense and then destroyed, can be replaced. Likewise lithographic methods, which include complex mask transfer processes or complex pattern transfer processes, can be replaced. The generation of a free standing ultra-thin membrane with dense fields of continuous pores with pore diameters less 100 nm is illustrated by way of example in FIGS. 6a-c. Fields of drops (5) of a photopolymerisable polymer with volumes of a few 10 zeptolitres are first deposited on surfaces (3) by means of LOS capillary nanoprinting, whereby advantageous alternative embodiments include the use of surfaces (3), which are oxidic or coated with gold. The ink drops (5) can be optionally solidified. In another step a further layer (10) is deposited on the surface (3) and the drops (5). By way of example this can happen by a SAM (“self assembled monolayer”) being produced as the further layer (10). Particularly advantageous are cross-linkable SAMs, for example diacetylene SAMs^{xlvi, xlvii} and/or phenyl SAMs and/or diphenyl SAMs,^{xlviii} which are cross-linked after deposition on surface (3). Optionally high temperature treatment can follow, in order to increase the graphite portion of the cross-linked SAMs. The drops (5) are released with a suitable method. For example this is possible mechanically, by ultrasound, by exposure to liquid streams, by dissolution in solvents, by chemical decomposition or thermal decomposition. The cross-linked SAM membranes are then removed from the surface (3). This can happen inter alia by fast change of temperature, etching the surface (3) completely or partially, swelling up with solvents, treatment with ultrasound, chemical release of the bonds between layer (10) and surface (3) (for instance with iodine vapour for breaking gold-sulfur bonds in the case of thiol on gold SAMs^{xlix}) or by mechanical removal. In an advantageous alternative embodiment easily soluble surfaces (3) consisting of recoverable materials as for instance crystalline potassium chloride are used. Layer (10) is thus maintained as free standing membrane with a thickness preferably of less than 50 nm, particularly preferably less than 10 nm and most preferably less than 5 nm, which has dense fields of pores with diameters preferably of less than 500 nm, particularly preferably less than 100 nm and most preferably less than 50 nm as well as nearest neighbour distances between the pores preferably of less than 500 nm and particularly less than 100 nm. Said membranes can have areas of more than 9 cm² for example. The membranes maintained in such a way can be produced in electrically conductive form or in semiconducting form, so that these have individual component Permian selectivity controllable via electro-chemical potentials and/or electro-chemically modulatable ion transport selectivity.

Furthermore many lithographic and/or topographic structuring processes according to the prior art require complex self-organsisation steps for producing self-organised structures, whose patterns are transferred into a further material, whereby said self-organised structures are destroyed during the pattern transfer. Examples of such lithographic and/or topographic structuring processes are block copolymer lithography or the generation of self-organised porous aluminium oxide by two-stage anodisation, whereby the self-organsisation of the fields of the growing pores takes place in a first anodisation step, lasting several hours up to several days. The porous aluminium oxide layer formed in the first anodisation step is then etched away, and the imprints of the pores of the etched away aluminium oxide layer in the remaining aluminium substrate in a second anodisation step serve as nuclei for the growth of pores in self-organised hexagonal arrays.^{xix, xx} Capillary nanoprinting combined with nano-drop lithography on the one hand replaces time-consuming self-organsisation steps for producing the patterns to be transferred, since the pattern is defined by the arrangement of the contact elements (2). Furthermore capillary nanoprinting combined with nano-drop lithography concerns the destruction of the self-organised structures produced by complex self-organsisation steps during the pattern transfer.

The generation of self-organised porous materials by capillary nanoprinting combined with nano-drop lithography is illustrated by way of example in FIGS. 6 a, d and e. Fields of ink drops (5) are applied on a material (12) by means of capillary nanoprinting. The ink is constituted so that this etches recesses (11) in material (12) at the positions, where ink drops are deposited. These recesses can serve as nuclei for pore growth in a further pore growth step, so that pores (13) are produced at the positions defined by capillary nanoprinting. For example if material (12) concerns aluminium, porous aluminium oxide may also be produced with pore arrangements defined by capillary nanoprinting. In this way the time-consuming first anodisation step in the generation of self-organised porous aluminium oxide can be avoided.

For example if a piece of aluminium (12) is brought into contact with fields of contact elements (2), which over an area of 9 cm² are arranged in a hexagonal array with a nearest neighbour distance of 65 nm, and if thereby drops of an ink are deposited on the piece of aluminium (12), which has the property of dissolving aluminium, fields of recesses (11) can be formed in the piece of aluminium (12), which over an area of 9 cm² are arranged in a hexagonal array with a nearest neighbour distance of 65 nm. In a following anodisation step fields of pores (13) may be produced in an aluminium oxide layer over an area of 9 cm² formed by anodisation with oxalic acid-containing electrolyte at 40 V, whereby the pores in this example are arranged in a hexagonal array with a nearest neighbour distance of approximately 65 nm. Said pores (13) form at the positions of the recesses (11), which act as nuclei for pore growth. The pores (13) in the example described here possess a diameter of preferably 35 nm as well as a length of preferably more than 1 μm, particularly preferably more than 10 μm and most preferably more than 100 μm. The arrangement of the recesses (11) in a piece of aluminium (12) in such a manner that the recesses (11) form a hexagonal array with a nearest neighbour distance, which corresponds to a nearest neighbour distance, which adjusts itself in at least one self-organised anodisation regime for producing self-organised porous aluminium oxide between the pores, is advantageous. If the arrangement of the contact elements (2) of the monolithic combinations of substrate (1) and contact elements (2) is implemented in such a way that this has a single-crystal degree of order, the pore arrangements in porous aluminium oxide obtained by means of capillary nanoprinting can have a higher degree of order than in self-organised porous aluminium oxide.

As illustrated by way of example in FIG. 7, capillary nanoprinting can be combined with metal-assisted etching of silicon,^{l-liv} in order to produce either porous silicon or fields of silicon nanowires. In an advantageous alternative embodiment the entire surface of a silicon wafer (14) is printed with capillary nanoprinting in one step. The combination of capillary nanoprinting with metal-assisted etching in this case solves the problem that, according to the prior art when generating either porous silicon or fields of silicon nanowires, masks must be produced, which in turn are destroyed in the process of metal-assisted etching of silicon, carried out according to the prior art. Examples of such sacrificial masks, whose generation and/or transfer are associated with substantial cost, are colloidal monolayers,^{li} blockcopolymer masks^{liii} and ultra-thin nano-porous aluminium oxide layers.^{liv} Porous silicon can be produced according to the invention for example by capillary nanoprinting of fields of ink drops (5) to be applied on a silicon wafer (14), whereby the ink has at least one precursor compound for a metal, which is suitable for metal-assisted etching. Said precursor compound for a metal, which is suitable for metal-assisted etching, is then converted into said metal. As a result fields of metal nanoparticles (15) are obtained on silicon wafer (14), whereby the position of the metal nanoparticles (15) is defined by the arrangement of the contact elements (2) in the monolithic combinations of substrate (1) and contact elements (2) (FIG. 7a). The fields of metal nanoparticles (15) preferably consist of nanoparticles of a metal that is selected from gold, silver, platinum and palladium. Further preferably the fields of metal nanoparticles (15) have a nearest neighbour distance of less than 100 nm and particularly preferably less than 60 nm. The metal nanoparticles (15) preferably possess a diameter of less than 100 nm, particularly preferably less than 60 nm and most preferably less than 30 nm. Pores are produced in silicon wafer (14) at the positions of the metal nano-particles (15) by metal-assisted etching (FIG. 7b).

Silicon nanowires may be produced inter alia as follows: first fields of drops of an ink (5) are applied on a silicon wafer (14) by capillary nanoprinting, whereby said ink drops can be optionally solidified (FIG. 7c). Subsequently the silicon wafer (14) is coated using suitable methods with a metal (16), suitable for metal-assisted etching (FIG. 7d). Preferably this metal is selected from gold, silver or platinum. Subsequent metal-assisted etching leads to dissolving of the silicon, where the silicon is in direct contact with metal (16), while there is no direct contact between silicon wafer (14) and metal (16) at the positions of the ink drops (5). Thus silicon nanowires with a diameter of preferably less than 100 nm, particularly preferably less than 50 nm and most preferably less than 20 nm as well as with lengths of preferably more than 100 nm, particularly preferably more than 1000 nm and most preferably more than 2 μm remain at the positions of the ink drops (5) (FIG. 7e). In an exemplary alternative embodiment the used combination of substrate (1) and contact elements (2) has hexagonal fields of contact elements (2) with a nearest neighbour distance of 100 nm and a surface density of 130 contact elements (2) per square micrometre. In this example fields of ink drops (5), solidified by means of suitable methods, with a nearest neighbour distance of 100 nm and a surface density of 130 ink drops (5) per square micrometre are obtained by capillary nanoprinting on a silicon wafer (14), freed beforehand from native oxide. In the next step a film consisting of a metal (16) suitable for metal-assisted etching is applied on silicon wafer (14) by a suitable method. In the described example the silicon nanowires obtained by subsequent metal-assisted etching form hexagonal fields with a nearest neighbour distance of 100 nm and a surface density of 130 silicon nanowires per square micrometre.

The principle of pseudo Ergodic laboratory in nano-drop configurations is illustrated by way of example in FIG. 8a. To produce pseudo Ergodic laboratory in nano-drop configurations first ink drops are printed on a surface (3) by means of capillary nanoprinting. Surface (3) is preferably implemented from a material, which is transparent for selected wavelength ranges of electromagnetic radiation. In a preferred alternative embodiment the fields of the ink drops are deposited by means of LIL capillary nanoprinting. Preferably the matrix liquid (6) in the liquid and/or solidified state covering surface (3) is transparent for selected wavelength ranges of electromagnetic radiation. Matrix liquid (6) can either be kept in the liquid state or solidified. As a result dense fields of encapsulated ink drops (5) can be obtained for example.

Preferably the dense fields of encapsulated liquid drops (5) are implemented so that individual liquid drops can be dissolved with optical microscopy. In an advantageous alternative embodiment for pseudo Ergodic laboratory in nano-drop configurations therefore a nearest neighbour distance between the encapsulated ink drops (5), which lies between 400 nm and 700 nm, was selected. Advantageous methods for microscopic observation of individual ink drops are for example confocal laser scanning microscopy, fluorescence microscopy or total internal reflection fluorescence microscopy (TIRF). Advantage of these methods is inter alia that a large number of different ink drops can be observed either successively or in parallel when resolving individual ink drops. Methods as for example single molecule spectroscopy and fluorescence correlation spectroscopy can also be used to investigate individual liquid drops. In this way for instance analyte molecules contained in individual ink drops can be observed during a longer period, whereby such observations of many ink drops can be repeated or carried out in parallel. FIG. 8a by way of example illustrates how a particular encapsulated ink drop is positioned in the focus volume (17) of a confocal laser scanning microscope, whereby either said ink drop can be observed over a longer period or a large number of ink drops can be observed successively in the scanning mode.

The encapsulated ink drops (5) can be used as parallel fields of nano-reactors for nano-chemistry ensemble investigations or as parallel fields of nano-containers for parallel ensemble investigations for example of the dynamics or fluorescence of analyte molecules. For example inks, which contain one kind or several kinds of analyte molecules, can be printed whereby the concentration of the analyte molecules can be selected in an advantageous way so that one analyte molecule is contained in one ink drop on average. This embodiment in an advantageous way exceeding the prior art permits the large scale parallel observation of molecular ensembles with resolving of single molecules. It is conceivable that at least one substance is supplied through the liquid or solidified matrix liquid to the individual ink drops of the fields of ink drops (5) by transport processes and changes taking place by said supply of at least one substance into the ink drops are observed with suitable methods. It is equally conceivable that at least one substance, contained in the ink drops, is totally or partially transferred by a transport process into the liquid or solidified matrix liquid (6), and the changes occurring as a result of said transfer into the ink drops can be examined with suitable methods. Preferably the printed surface (3) in contact with the ink drops (5) is catalytically active. For example it is conceivable that surface (3) consists of titanium oxide or a material coated with titanium oxide and has photo-catalytic activity. In this way can be investigated for instance how dyestuff molecules selected in many parallel-arranged ink drops are bleached. It is conceivable to characterize the catalytic activity of surfaces with high throughput by means of pseudo Ergodic laboratory in nano-drop configurations. It is likewise conceivable to observe the time dependence of the fluorescence of dyestuff molecules, the three-dimensional orientation and/or rotational movement diffusion of transmission dipole moments of dyestuff molecules, the molecular dynamics of selected molecules as well as reversible or irreversible isomerisations as for example photo isomerisations in pseudo Ergodic laboratory in nano-drop configurations. Preferably such observations are implemented in such a manner that these are realised on the one hand on particular analyte molecules, in each case contained in an ink drop but that on the other hand such observations are carried out in parallel or successively on many different ink drops.

Pseudo Ergodic lab on chip configurations, which preferably permit parallel single molecule detection of analyte molecules on a large-scale, can be produced via deposition of fields of ink drops (5) on surfaces (3), whereby the ink drops solidify for example by evaporating a volatile component and the solidified ink drops preferably form dot-like coatings (18) on the surface (3). The principle of pseudo Ergodic lab on chip configurations is illustrated in FIG. 8b. An advantageous alternative embodiment of the formation of said dot-like coatings (18) includes the binding of the material, of which said dot-like coatings (18) consist, to the surface (3) via covalent bonds and/or via hydrogen bonds and/or via electrostatic interactions, which can be present in the form of van der Waals interactions and/or in the form of reciprocal effects between charged particles and/or charged surfaces. In a possible alternative embodiment the top layer of the surface (3) consists of gold or hydroxyl groups. The material, of which the dot-like coatings (18) consist, can bond to surface (3) inter alia via thiol groups and/or via silane groups and/or via halogenosilane groups and/or via alkosilane groups and/or via phosphonate groups and/or 1-alkenyl groups. Furthermore the material, of which the dot-like coatings (18) consist, can have at least one further functional group, which does not form any bond to surface (3), or combinations of at least two further functional groups, which in each case do not form any bonds to surface (3). Said functional groups, which do not form any bonds to surface (3), can for example be selected from alkyl groups, derivatives of alkyl groups, alkenyl groups, alkinyl groups, phenyl groups, derivatives of phenyl groups, halogen alkyl groups, halogen aryl groups, hydroxyl groups, carbonyl groups, aldehyde groups, carboxyl groups, ketol groups, carbonate groups, ether groups, ester groups, alkoxy groups, peroxo groups, acetal groups, semi acetal groups, amino groups, amido groups, imino groups, imido groups, azido groups, azo groups, cyanate groups, nitrate groups, nitrilo groups, nitrito groups, nitro groups, nitroso groups, pyirdino groups, thiol groups, sulfide groups, disulfide groups, sulfoxide groups, sulphonyl groups, sulfino groups, sulfo groups, thiocyanate groups, sulfate groups, sulfonate groups, phosphine groups, phosphonate groups and/or phosphate groups.

The material, of which the dot-like coatings (18) consist, can form for example SAMs (“self assembled monolayers”). The dot-like coatings (18) preferably have diameters of less than 100 nm, particularly preferably less than 50 nm and most preferably less than 20 nm. In an advantageous alternative embodiment of pseudo Ergodic lab on chip configurations the nearest neighbour distance between the dot-like coatings (18) is selected in such a way that this amounts to minimum 400 nm and maximum 700 nm, so that individual dot-like coatings (18) can be dissolved in each case by means of optical microscopy. Advantageous methods for microscopic study of ensembles of dot-like coatings (18) with resolving of individual dot-like coatings are for example confocal laser scanning microscopy, fluorescence microscopy or total internal reflection fluorescence microscopy. Therefore a large number of individual immobilisation events with resolving of single molecules can be observed successively and/or in parallel for example. It is also conceivable to use raster-probe-microscopic methods to observe bonding or immobilisation events on the dot-like coatings (18).

In each case an analyte molecule can be immobilised by means of suitable methods for example for each dot-like coating (18). For example however it is equally conceivable that several analyte molecules are immobilised for each dot-like coating (18). Analyte molecules can be immobilised by non-specific adsorption for example. Pre-concentration sensors can be operated for instance on the basis of non-specific adsorption of analyte molecules, whereby the number of immobilised molecules for each dot-like coating (18) can be determined via fluorescence intensities for example. Likewise it is conceivable that the dot-like coatings (18) are modified chemically or biochemically in such a manner that selected analyte molecules specifically bond to the dot-like coatings (18). The dot-like coatings (18) can be modified for instance by means of affinity tags, antigens or antibodies. In a particularly advantageous alternative embodiment for pseudo Ergodic lab on chip configurations non-specific adsorption is prevented. Pseudo Ergodic lab on chip configurations can be used for immunoassays and/or for investigating antigen antibody affinities for example. In an advantageous alternative embodiment of pseudo Ergodic lab on chip configurations immobilisation of an antibody and/or an antigen for each dot-like coating (18) takes place in a way known as “site-directed” in each case.

The features of the invention disclosed in the above description, in the claims as well as in the enclosed drawings can be essential, both individually and in any combination, for carrying out the invention in its various embodiments.

### REFERENCES CITED IN NOTES

ⁱ K. Maejima, S. Tomikawa, K. Suzuki, D. Citterio, RSC Adv. 2013, 3, 9258.
ⁱⁱ Z. Dong, J. Ma, L. Jiang, ACS Nano 2013, 11, 10371.
ⁱⁱⁱ A. Jaworek, A. T. Sobczyk, J. Electrostat. 2008, 66, 197.
^{iv} R. D. Piner, J. Zhu, F. Xu, S. H. Hong, C. A. Mirkin, Science 1999, 283, 661.
^{v} A. B. Braunschweig, F. Huo, C. A. Mirkin, Nat. Chem. 2009, 1, 353.
^{vi} B. Basnar, I. Willner, Small 2009, 5, 28.
^{vii} L. G. Rosa, J. Liang, J. Phys. Condens. Matter 2009, 21, 483001.
^{viii} Z. Xie, X. Zhou, X. Tao, Z. Zheng, Macromol. Rapid Commun. 2012, 33, 359.
^{ix} Y. Xia, G. M. Whitesides, Annu. Rev. Mater. Sci. 1998, 28, 153.
^{x} M. Cavallini, F. Biscarini, Nano Lett. 2003, 3, 1269.
^{xi} L. J. Guo, Adv. Mater. 2007, 19, 495.
^{xii} F. Huo, Z. Zheng, G. Zheng, L. R. Giam, H. Zhang, C. A. Mirkin, Science 2008, 321, 1658.
^{xiii} A. Meister, M. Liley, J. Brugger, R. Pugin, H. Heinzelmann, Appl. Phys. Lett. 2004, 85, 6260.
^{xiv} S. G. Vengasandra, M. Lynch, J. T. Xu, E. Henderson, Nanotechnology 2005, 16, 2052.
^{xv} A. Fang, E. Dujardin, T. Ondarcuhu, Nano Lett. 2006, 6, 2368.
^{xvi} L. Fabié, T. Ondarcuhu, Soft Matter 2012, 8, 4995.
^{xvii} J. Hu, M.-F. Yu, Science 2010, 329, 313.
^{xviii} J. J. Dumond, H. Y. Low, J. Vac. Sci. Technol. B 2012, 30, 010801.
^{xx} H. Masuda, K. Fukuda, Science 1995, 268, 1466.
^{xx} H. Masuda, K. Yada, A. Osaka. Jpn. J. Appl. Phys. 1998, 37, L1340.
^{xxi} S. Grimm et al., Nano Lett. 2008, 8, 1954.
^{xxii} G. T. Rengarajan, L. Walder, S. N. Gorb, M. Steinhart, ACS Appl. Mater. Interf. 2012, 4, 1169.
^{xxiii} M. Steinhart, G. T. Rengarajan, H. Schäfer, Körper aus einem Matrixmaterial sowie Verfahren zur Herstellung and Verwendung eines solchen Körpers. German Patent DE 10 2011 053 612 issued 20 Sep. 2012.
^{xxiv} H. J. Nam, D.-Y. Jung, G.-R. Yi, H. Choi, Langmuir 2006, 22, 7358.
^{xxv} Y. Wang, U. Gösele, M. Steinhart, Chem. Mater. 2008, 20, 379.
^{xxvi} Y. Wang, U. Gösele, M. Steinhart, Nano Lett. 2008, 8, 3548.
^{xxii} Y. Wang, L. Tong, M. Steinhart, ACS Nano 2011, 5, 1928.
^{xxviii} L. Xue, A. Kovalev, F. Thole, G. T. Rengarajan, M. Steinhart, S. N. Gorb, Langmuir 2012, 28, 10781.
^{xxix} Y. Wang, C. He, W. Xing, F. Li, L. Tong, Z. Chen, X. Liao, M. Steinhart, Adv. Mater. 2010, 22, 2068.
^{xxx} R. Deng, S. Liu, J. Li, Y. Liao, J. Tao, J. Zhu, Adv. Mater. 2012, 24, 1889.
^{xxxi} N. Zhou, F. S. Bates, T. P. Lodge, Nano Lett. 2006, 6, 2354.
^{xxxii} T. Leïchlè, L. Tanguy, L. Nicu, Appl. Phys. Lett. 2007, 91, 224102.
^{xxxiii} K. Kaisei, N. Satoh, K. Kobayashi, K. Matsushige, H. Yamada, Nanotechnology 2011, 22, 175301.
^{xxxiv} F. Mugele, J.-C. Baret, J. Phys.: Condens. Matter 2005, 17, R705.
^{xxxv} R. Shamai, D. Andelman, B. Berge, R. Hayes, Soft Matter 2008, 4, 38.
^{xxxvi} C. Laslau, D. E. Williams, J. Travas-Sejdic, Prog. Polym. Sci. 2012, 37, 1177.
^{xxxvii} N. Aydemir et al., Macromol. Rapid Commun. 2013, 34, 1296.
^{xxxviii} K. McKelvey, M. A. O'Connell, P. R. Unwin, Chem. Commun. 2013, 49, 2986.
^{xxxix} A. Zabala Ruiz, H. Li, G. Calzaferri, Angew. Chem. Int. Ed. 2006, 45, 5282.
^{xl} K. B. Yoon, Acc. Chem. Res. 2007, 40, 29.
^{xli} J. S. Beck et al., J. Am. Chem. Soc. 1992, 114, 10834.
^{xlii} D. Zhao et al., Science 1998, 279, 548.
^{xliii} V. Alfredsson, M. W. Anderson, Chem. Mater. 1996, 8, 1141.
^{xliv} K. M. McGrath, D. M. Dabbs, N. Yao, I. A. Aksay, S. M. Gruner, Science 1997, 277, 552.
^{xlv} Y. Lu et al., Nature 1997, 389, 364.
^{xlvi} H. Menzel, M. D. Mowery, M. Cai, C. E. Evans, J. Phys. Chem. B 1998, 102, 9550.
^{xlvii} H. Menzel, S. Horstmann, M. D. Mowery, M. Cai, C. E. Evans, Polymer 2000, 41, 8113.
^{xlviii} Y. Wang, R. Xiong, L. Dong, A. Hu, J. Mater. Chem. A 2014, 2, 5212.
^{xlix} W. Eck, A. Küller, M. Grunze, B. Völkel, A. Gôlzhâuser, Adv. Mater. 2005, 17, 2583.
^{l} X. Li, P. W. Bohn, Appl. Phys. Lett. 2000, 77, 2572.
^{li} Z. Huang, H. Fang, J. Zhu, Adv. Mater. 2007, 19, 744.
^{lii} K. Peng, A. Lu, R. Zhang, S.-T. Lee, Adv. Funct. Mater. 2008, 18, 3026.
^{liii} S.-W. Chang, V. P. Chuang, S. T. Boles, C. A. Ross, C. V. Thompson, Adv. Funct. Mater. 2009, 19, 2495.
^{liv} Z. Huang et al., Nano Lett. 2009, 9, 2519.
^{lvlv} A. Makaraviciute, A. Ramanaviciene, Biosensors Bioelectronics 2013, 50, 460.

1. Device for carrying out a capillary nanoprinting method, comprising at least one monolithic combination of a substrate and one or more contact elements, wherein at least parts of the contact elements have a porous structure.

2. Device for carrying out a capillary nanoprinting method according to claim 1, wherein the porous structure has an isotropic or anisotropic continuous pore system.

3. Device according to claim 1, wherein the surface of the monolithic combination of substrate and the one or more contact elements at least partially has pore openings facing away from the substrate and a portion of the pore openings on the parts having pore openings of the total surface of the monolithic combination of substrate and contact elements is greater than 10%.

4. Device according to claim 1, wherein the monolithic combination of substrate and contact elements contains at least one material, which is selected from:
i) organic polymers selected from poly(p-xylene), polyacrylamide, polyimides, polyesters, polyolefins, polystyrenes, polycarbonates, polyamides, polyethers, polyphenyls, polysilanes, polysiloxanes, polybenzimidazoles, polybenzthiazoles, polyoxazoles, polysulfides, polyester amides, polyarylene vinylenes, polylactides, polyetherketones, polyurethanes, polysulfones, inorganic and organic hybrid polymers, polyacrylates, silicones, fully aromatic co-polyesters, poly N vinylpyrrolidone, polyhydroxyethyl methacrylate, polymethyl methacrylate, polyethylene teraphthalate, polybutylene teraphthate, polymethacrylic nitrile, polyacrylic nitrile, polyvinyl acetate, neoprene, Buna N, polybutadiene, polyethylene,
ii) fluorine-containing polymers selected from polyvinylidene difluoride, polytrifluorethylene, polytetrafluoroethylene, polyhexaflouropropylene,
iii) dendrimers and/or star-shaped polymers and/or comb-like polymers,
iv) biological polymers selected from polysaccharides, cellulose modified or non-modified, alginates, polypeptides, collages, DNA, RNA,
v) polymers, which are composed of at least two different repeating units,
vi) block copolymers, which contain at least two blocks of different polarity, wherein said blocks are selected from polystyrene blocks and/or polyisoprene blocks and/or polybutadiene blocks and/or polypropylene blocks and/or polyethylene blocks and/or poly (methylmethacrylate)-blocks and/or poly (vinylpyridin)-blocks and/or poly (vinylpyrrolidone)-blocks and/or poly (vinyl alcohol)-blocks and/or poly (ethyl oxide)-blocks and/or poly (propylene oxide)-blocks and/or poly (butylmethacrylate)-blocks and/or poly (N-isopropyl acrylamide)-blocks and/or poly (dimethylsiloxane)-blocks and/or polyacrylate-blocks and/or poly (vinyl acetate)-blocks and/or poly (vinylidene difluoride)-blocks and/or polythiophene blocks and/or poly (styrene sulfonate)-blocks,
vii) copolymers, which contain fluorine-containing comonomers,
viii) conductive and/or semiconducting polymers,
ix) polyelectrolytes,
x) combinations of two or more polymers and/or inorganic materials,
xi) metals,
xii) any mixtures of different metals,
xii) oxides, which contain at least one metal and oxygen or at least one semiconductor and oxygen,
xiii) inorganic semiconductors,
and mixtures thereof.

5. Device according to claim 1, wherein the contact elements are rod-shaped, cylindrical, spherical, hemispherical, rectangular, square, strip-shaped, tubular or hollow cylinder shaped.

6. Device according to claim 3, wherein ends of the contact elements (2) facing away from the substrate (1) are hemispherical, pyramidal or even or represent hollow cylinder openings.

7. Device according to claim 1, wherein a side of the substrate facing away from the contact elements is connected to a further porous layer.

8. Device according to claim 1, wherein the substrate is cylindrical or cylinder jacket-shaped and the contact elements are arranged on an outer surface of the cylindrical or cylinder jacket-shaped substrate.

9. Method for carrying out a capillary nanoprinting, comprising the steps:
a) providing a device according to claim 1;
b) providing a surface to be printed;
c) providing an ink in at least one part of the porous structure of the monolithic combination;
d) reducing the distance between the surface to be printed and the contact elements, in order to form one or more capillary bridges consisting of ink between the contact elements and the surface to be printed;
e) subsequently increasing the distance between the contact elements and the surface to be printed, to keep the contact elements and the surface apart from one another at a specific constant distance for a selected time after being brought near each other and before the distance is increased or to increase the distance immediately after the contact elements and the surface have been brought near each other.

10. Method for carrying out a capillary nanoprinting, comprising the steps:
a) providing a device according to claim 8;
b) providing a surface to be printed;
c) providing an ink in at least a portion of the porous structure of the monolithic combination;
d) reducing the distance between the surface to be printed and the contact elements, the reduction of the distance between the surface to be printed and the contact elements taking place before or after the providing an ink in at least one part of the porous structure of the monolithic combination;
e) moving the surface to be printed so as to contact the device, in which the monolithic combination of substrate and contact elements implements a rotational movement about its longitudinal axis, or rolling the monolithic combination of substrate and contact elements, contained in the device over the surface, and
f) rotationally moving the monolithic combination of substrate and contact elements, contained in the device, about its longitudinal axis, relative to the surface to be printed in such a manner that capillary bridges consisting of ink, which break while the rotational movement continues and when the contact elements are removed from the surface (3) in this way, initially form between the contact elements facing the surface and the surface, whereas new capillary bridges form between the contact elements newly facing the surface and the surface, which in turn break resulting from continuation of the rotational movement, whereby this method can be continued further according to the requirements of the application.

11. Method according to claim 9, wherein the ink is advanced to the contact elements continuously or in phases.

12. Method according to claim 9, wherein the distance between the contact elements and the surface to be printed is reduced and/or increased at a speed of maximum 1 μm per second.

13. Method according to claim 9, wherein formation of the capillary bridge consisting of ink is detected by measuring the force necessary for bringing the elements and the surface near each other and/or by creating an electrical contact between the monolithic combination of the substrate and the contact elements as well as the surface to be printed.

14. Method according to claim 9, wherein the method is carried out in the presence of an electric and/or magnetic field.

15. Method according to claim 9, wherein when the distance between the contact elements and the surface to be printed is increased, the capillary bridges consisting of ink are broken, in order to produce ink drops on the surface to be printed.

16. Method according to claim 9, wherein the capillary bridges are solidified at least partially while or after the distance between the contact elements and the surface to be printed is increased before the capillary bridges break.

17. Field of ink drops or of their derived products on a surface, obtained according to the method of claim 9, wherein the ink drops or their derived products have a volume of maximum one picolitre in each case.

18. Field of wires or their derived products obtained according to the method of claim 9 consisting of wires or their derived products, wherein the longitudinal axes of the wires or of their derived products with surface include an angle of 90° or less.

19. Field of wires or their derived products obtained according to the method of claim 9, wherein the wires or their derived products have a diameter of less than 500 nm.

20. Field of wires or their derived products obtained according to the method of claim 9, wherein the wires or their derived products have a length of more than 500 nm.

21. Field of coatings or of their derived products on a surface, obtained according to the method of claim 9, wherein the coatings or their derived products have a diameter of less than one micrometre in each case.

22. Field according to claim 17, wherein the field has an area preferably of at least 100 square micrometres.

23. Field according to claim 17, wherein the field forming ink drops and/or derived products of ink drops have a distance to their nearest neighbours within the field of less than one micrometre in each case.

24. Field according to claim 17, wherein the field forming ink drops and/or derived products of ink drops forms a regular lattice.

25. Field according to claim 17, wherein the field has a surface density of more than one ink drop or derived product per square micrometre.

26. (canceled)
